(19) United States
(12) Patent Application Publication
(10) Pub. No.: US 2026/0107489 A1
(43) Pub. Date: Apr. 16, 2026

(54) HIGH VOLTAGE FINFET DEVICE AND METHOD

(71) Applicant: Taiwan Semiconductor Manufacturing Company, Ltd., Hsinchu (TW)

(72) Inventors: Yi-Hong Wang, Taichung City (TW); Yi-Chen Li, Taichung City (TW); Hui-Hsuan Kung, Taichung City (TW); Chih-Hsiao Chen, Taichung City (TW); Jung-You Chen, Zhubei City (TW)

(73) Assignee: Taiwan Semiconductor Manufacturing Company, Ltd., Hsinchu (TW)

(21) Appl. No.: 18/915,598

(22) Filed: Oct. 15, 2024

(51) Int. Cl. H01L 29/772; H01L 29/66; H01L 29/78

(52) U.S. Cl. CPC H10D 30/204; H10D 30/024; H10D 30/6215

(57) ABSTRACT

A semiconductor structure is disclosed that includes: a source region and a drain region in a substrate; a first gate structure disposed above a first channel region in the substrate and between the source region and the drain region wherein the first gate structure includes a first gate dielectric disposed above the first channel region and a first gate electrode disposed above the first gate dielectric; and a second gate structure disposed above a second channel region in the substrate and between the first gate structure and the drain region, wherein the first gate structure is disposed closer to the source region and the second gate structure is disposed closer to the drain region.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of an example high voltage device that includes multiple gate structures in series between a source region and a drain region, according to some embodiments.

FIG. 1B is a cross-sectional view of the control gate, according to some embodiments.

FIG. 1C is a cross-sectional view of the control gate, according to some embodiments.

FIG. 1D is a cross-sectional view of the modulated gate, according to some embodiments.

FIG. 1E is a cross-sectional view of the modulated gate, according to some embodiments.

FIG. 1F is a cross-sectional view of the high voltage device, according to some embodiments.

FIG. 2A is a cross-sectional view along the X-X′ cut line 2 illustrating a charge state of the modulated gate at the start of an on-state of the high voltage device, according to some embodiments.

FIG. 2B is a cross-sectional view along the X-X′ cut line 2 illustrating a charge state of the modulated gate after carriers of the trapping layer have been filled with electrons during the on-state of the high voltage device, according to some embodiments.

FIG. 2C is a cross-sectional view along the X-X′ cut line 2 illustrating a charge state of the modulated gate during the off-state of the high voltage device 100, according to some embodiments.

FIG. 2D is a cross-sectional view along the Y-Y′ cut line 2 illustrating the charge state of the modulated gate during the off-state of the high voltage device, according to some embodiments.

FIG. 3A is a top view of an example semiconductor structure that includes multiple gate structures in series between a source region and a drain region, according to some embodiments.

FIG. 3B is a flow chart depicting an example method of fabricating a high voltage device that includes multiple gate structures in series between a source region and a drain region, according to some embodiments.

FIG. 4A illustrates that a PMOS high voltage FinFET device may benefit from a high work function metal (Ψm≥5.0), such as Pt or Au, according to some embodiments.

FIG. 4B illustrates that an NMOS high voltage FinFET device may benefit from a low work function metal (Ψm≤4.1), such as Ti or Al, according to some embodiments.

FIG. 4C depicts a cross-sectional view of the example modulated gate during an off-state, according to some embodiments.

FIG. 4D depicts a cross-sectional view of the example modulated gate during an off-state, according to some embodiments.

FIG. 5A is a top view of an example high voltage device that includes multiple gate structures in series between a source region and a drain region, according to some embodiments.

FIG. 5B is a cross-sectional view of a depleted gate along an X-X′ cut line 3, according to some embodiments.

FIG. 5C is a cross-sectional view of the high voltage device along a fin between the control gate and the depleted gate, according to some embodiments.

FIG. 5D is a cross-sectional view of the high voltage device along a fin between the control gate and the depleted gate with implant doping in the CESL to extend the slight doping depletion channel region to make the breakdown voltage even larger, according to some embodiments.

FIG. 5E is a flow chart depicting an example method 550 of fabricating a high voltage device that includes multiple gate structures in series between a source region and a drain region, according to some embodiments.

FIG. 5F is a cross-sectional view of an example high voltage device that includes multiple gate structures in series between a source region and a drain region, according to some embodiments.

FIG. 6A is a top view of an example high voltage device that includes multiple gate structures in series between a source region and a drain region, according to some embodiments.

FIG. 6B is a cross-sectional view of an anti-type depleted gate along an X-X′ cut line 4 in an on-state, according to some embodiments

FIGS. 6C and 6D are cross-sectional views of an anti-type depleted gate along the X-X′ cut line 4 in an off-state, according to some embodiments.

FIG. 6E is a flow chart depicting an example method of fabricating a high voltage device that includes multiple gate structures in series between a source region and a drain region, according to some embodiments.

FIG. 7A is a top view of an example high voltage device that includes multiple gate structures in series between a source region and a drain region, according to some embodiments.

FIG. 7B is a top view of an example high voltage device that includes multiple gate structures in series between a source region and a drain region, according to some embodiments.

FIG. 7C is a top view of an example high voltage device that includes multiple gate structures in series between a source region and a drain region, according to some embodiments.

FIG. 7D is a top view of an example high voltage device that includes multiple gate structures in series between a source region and a drain region, according to some embodiments.

FIG. 7E is a top view of an example high voltage device that includes multiple gate structures in series between a source region and a drain region, according to some embodiments.

FIG. 7F is a top view of an example high voltage device that includes multiple gate structures in series between a source region and a drain region, according to some embodiments.

FIG. 8A is a cross-sectional view of an example NMOS high voltage device that includes multiple gate structures in series between a source region and a drain region, according to some embodiments.

FIG. 8B is a cross-sectional drawing of the anti-type depleted gate, according to some embodiments.

FIG. 8C is a cross-sectional view of an example PMOS high voltage device, according to some embodiments.

FIG. 8D is a cross-sectional drawing of the anti-type depleted gate, according to some embodiments.

FIG. 8E is a cross-sectional view of a depleted gate around a channel layer, along a Y-Y′ cut line of a high voltage device, according to some embodiments.

FIG. 8F is a diagram illustrating electrical properties of the depleted gate, according to some embodiments.

FIG. 9A is a top view of an example high voltage device that includes multiple gate structures in series between a source region and a drain region, according to some embodiments.

FIG. 9B is a cross-sectional view of the high voltage device, according to some embodiments.

FIG. 9C is a cross-sectional view of the high voltage device during an on-state with a current flow through the metal line, according to some embodiments.

FIG. 9D is another cross-sectional view of the high voltage device during an on-state, according to some embodiments.

FIG. 9E is another cross-sectional view of the high voltage device during an on-state, according to some embodiments.

FIG. 9F is a cross-sectional view of another embodiment of the high voltage device, according to some embodiments.

FIG. 10A is a top view of an example high voltage device that includes multiple gate structures in series between a source region and a drain region, according to some embodiments.

FIG. 10B is a top view of an example high voltage device that includes multiple gate structures in series between a source region and a drain region, according to some embodiments.

FIG. 11A is a top view of an example high voltage device that includes multiple gate structures in series between a source region and a drain region, according to some embodiments.

FIG. 11B is a cross-sectional view of the example high voltage device, according to some embodiments.

FIG. 11C is a cross-sectional view of an example high voltage device, in accordance with some embodiments.

FIG. 12 is a top view of an example semiconductor structure that includes multiple gate structures in series between a source region and a drain region, according to some embodiments.

FIG. 13A is a cross-sectional view of the high voltage device that includes multiple gate structures in series between a source region and a drain region, according to some embodiments.

FIG. 13A illustrates on-state operation of the high voltage device, according to some embodiments.

FIG. 13B is a cross-sectional view of the high voltage device that illustrates off-state operation of the high voltage device, according to some embodiments.

FIG. 14A is a flow diagram of an example method for fabricating a semiconductor device, according to some embodiments.

FIG. 14B is a cross-sectional view of a semiconductor device at a stage of fabrication, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

As used herein, the terms such as “first,” “second” and “third” describe various elements, components, regions, layers and/or sections, these elements, components, regions, layers, and/or sections should not be limited by these terms. These terms may be only used to distinguish one element, component, region, layer, or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5° less than or equal to ±4°, less than or equal to ±3°, less than or equal to ±2°, less than or equal to ±1°, less than or equal to ±0.5°, less than or equal to ±0.1°, or less than or equal to ±0.05°.

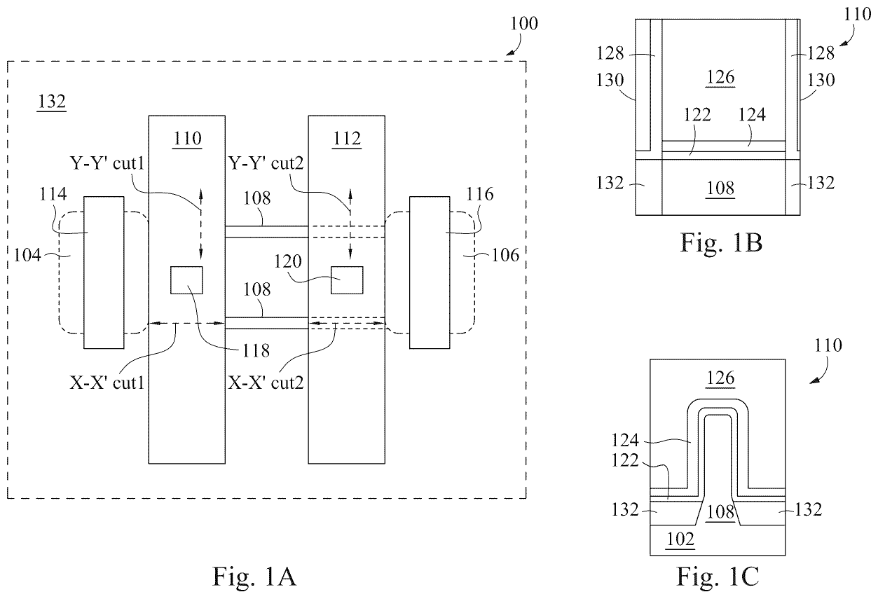

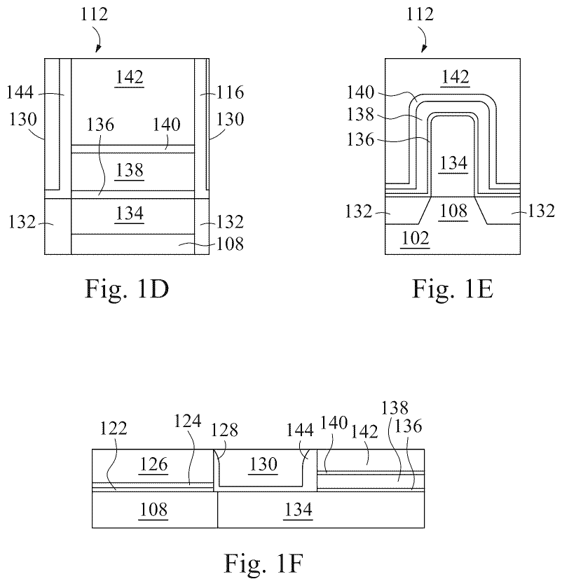

FIG. 1A is a top view of an example high voltage device 100 that includes multiple gate structures in series between a source region and a drain region, according to some embodiments. The example high voltage device 100 is a high voltage FinFET device for use in many high voltage applications such as amplifiers, including microwave power amplifiers, RF power amplifiers and audio power amplifiers, among others. The example high voltage device 100 includes a control gate for turning the high voltage FinFET device on or off, and a secondary gate for improving the device's high voltage performance. In this example, the secondary gate is a modulated gate.

The example high voltage device 100 is formed on a substrate (e.g., p-type substrate) that includes a source region 104, a drain region 106, one or more fins 108 disposed between the source region 104 and the drain region 106, and a shallow trench isolation feature 132 for isolating various components. The high voltage device 100 further includes a control gate 110 disposed over the one or more fins 108 between the source region 104 and the drain region 106 and adjacent to the source region 104, and a modulated gate 112 disposed over the one or more fins 108 between the source region 104 and the drain region 106 and adjacent to the drain region 106. The high voltage device 100 also includes a source terminal 114 for the source region 104, a drain terminal 116 for the drain region 106, a control gate terminal 118 for the control gate 110, and a modulated gate terminal 120 for the modulated gate 112.

The modulated gate 112 has a heavily doped channel (not shown) and a special gate structure described below with reference to FIGS. 1D and 1E. Use of the modulated gate 112 allows the distance between the drain region 106 and the control gate 110 to be shorter for high voltage applications therefore reducing substrate area needed to accommodate the high voltage device 100. Because the high voltage device 100 includes both a control gate 110 and a modulated gate 112, the high voltage device 100 includes a control channel (not shown) under the control gate 110 and a modulated channel (the highly doped channel) under the modulated gate 112.

FIG. 1B is a cross-sectional view of the control gate 110 along an X-X′ cut line 1, and FIG. 1C is a cross-sectional view of the control gate 110 along a Y-Y′ cut line 1. The example control gate 110 as depicted includes a fin 108 on the substrate 102 disposed between STI features 132, an IL 122 (interfacial layer) disposed above the fin 108, an HK dielectric layer 124 (high-K dielectric layer) disposed above the IL 122, and a metal gate material layer 126 disposed above the HK dielectric layer 124 and disposed between a CESL 128 (contact etch stop layer) and an interlayer dielectric layer 130 (ILD0). In various embodiments, the fin 108 comprises pure silicon (Si) or is slightly p-doped. In various embodiments, the doping of the slightly p-doped fin is less than 5×10¹⁶ parts per cm³.

FIG. 1D is a cross-sectional view of the modulated gate 112 along an X-X′ cut line 2, and FIG. 1E is a cross-sectional view of the modulated gate 112 along a Y-Y′ cut line 2. The example modulated gate 112 as depicted includes a fin 108 on the substrate 102 disposed between STI features 132 wherein the fin 108 includes a highly doped portion 134, a tunneling oxide layer 136 disposed above the highly doped portion 134, a trapping layer 138 disposed above the tunneling oxide layer 136, a control oxide layer 140 disposed above the trapping layer 138, and a metal gate material layer 142 disposed above the control oxide layer 140 and disposed between a contact CESL 144 and ILD0 130.

In various embodiments, the highly doped portion 134 comprises a highly doped N-well (N+) region of a Si fin. In various embodiments, the control oxide layer 140 comprises an HK oxide. In various embodiments, the tunneling oxide layer 136 comprises a thin SiO₂ layer. In various embodiments, the doping of the highly doped portion 134 is greater than 2×10¹⁸ parts per cm³. In various embodiments, the control oxide layer 140 has a thickness that is greater than the thickness of the tunneling oxide layer 136. In various embodiments the tunneling oxide layer 136 has a thickness that is greater than or equal to 8 Angstroms (Å).

In various embodiments, the metal gate material layer 142 comprises a work function metal composition. In various embodiments the work function metal composition comprises Ag, Au, Al, Rh, W, Mo, Zn, Co, Ru, Nb, Ti, Ta, Zr, and/or metal compound/Alloy (TiN, Brass, Phosphor bronze, Cast steel, etc.). In various embodiments, the control oxide layer 140 comprises Si, Hf, La, Zr, Zn, Y, or others. In various embodiments, the tunneling oxide layer 136 comprises Si, O, or others. In various embodiments, the trapping layer 138 comprises Si, Ge, InSb, InAs, InP, N, Hf, Zr, Zn, Y, or others. In various embodiments, the fin 108 comprises Si, C, N, Ge, Ga, Sb, In, As, P, Al, Sn, or others.

FIG. 1F is a cross-sectional view of the high voltage device 100 along and between X-X′ cut line 1 and X-X′ cut line 2. Depicted are the fin 108 and the highly doped portion 134 of the fin 108, the IL 122 disposed above the fin 108 of the control gate 110, a the HK dielectric layer 124 disposed above the IL 122, the metal gate material layer 126 for the control gate 110 disposed above the HK dielectric layer 124, the tunneling oxide layer 136 disposed above the highly doped portion 134 of the modulated gate 112, the trapping layer 138 disposed above the tunneling oxide layer 136, the control oxide layer 140 disposed above the trapping layer 138, and the metal gate material layer 142 of the modulated gate 112 disposed above the control oxide layer 140. Also, depicted are the CESL 128 around the control gate 110, the contact CESL 144 around the modulated gate 112, and the ILD0 130 disposed between the CESL 128 and the contact CESL 144 and disposed above the highly doped portion 134 of the fin 108 that is between the control gate 110 and the modulated gate 112.

FinFET devices can have a narrow channel and provide a small junction. A small junction can provide a depletion region in a channel due to an electric field from the drain. To reduce channel depletion, some high voltage devices extend the distance between the gate and the drain to reduce the electric field. The example high voltage device 100 is configured to reduce electric field through the use of the modulated gate. Use of the modulated gate can reduce the electric filed during the off-state with less extended distance between the gate and the drain. The example high voltage device 100 therefore saves area or space on the substrate.

The modulated gate 112 is configured to trap charge in the trapping layer 138 during an on-state to reduce a depletion region during an off-state. The use of the highly doped portion 134 allows for a heavily doped channel under the modulated gate 112, which results in lower resistance provided by the heavily doped channel so that the on-state current can be larger. During the off-state, the drain region 106 has a higher voltage and stronger electric field than the source region 104 and creates a depletion region in a channel region between the source region 104 and the drain region 106. During the off-state, the charge in the trapping layer 138 is released to the source side of the channel under the modulated gate 112 to reduce the electric field formed by the drain region 106 and reduce the channel depletion region.

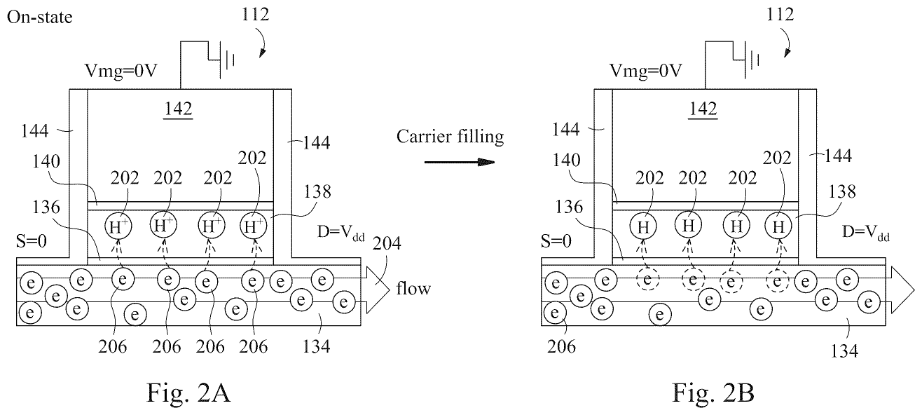

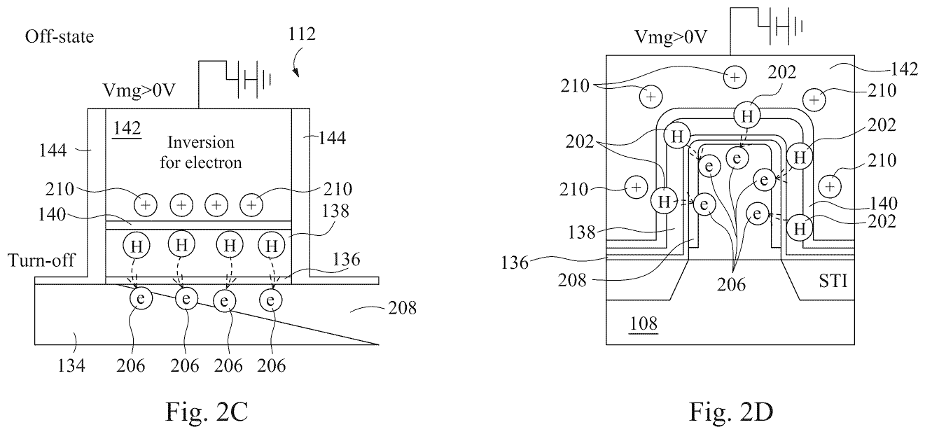

FIG. 2A is a cross-sectional view along the X-X′ cut line 2 illustrating a charge state of the modulated gate 112 at the start of an on-state of the high voltage device 100. In the example embodiment, during the on-state, the modulated gate 112 has a source voltage of around 0V, a drain voltage of V_{dd}, and a gate voltage V_{mg} of 0V. The trapping layer 138 is doped with a plurality of carriers 202. During this on-state, current 204 flows from source to drain and some of the electrons 206 from the current flow are captured by the plurality of carriers 202 in the trapping layer 138. FIG. 2B is a cross-sectional view along the X-X′ cut line 2 illustrating a charge state of the modulated gate 112 after carriers 202 of the trapping layer 138 have been filled with electrons 206 during the on-state of the high voltage device 100.

FIG. 2C is a cross-sectional view along the X-X′ cut line 2 illustrating a charge state of the modulated gate 112 during the off-state of the high voltage device 100, and FIG. 2D is a cross-sectional view along the Y-Y′ cut line 2 illustrating the charge state of the modulated gate 112 during the off-state of the high voltage device 100. In the example embodiment, during the off-state, the modulated gate 112 has a source voltage of around 0V, a drain voltage of V_{dd}, and a gate voltage V_{mg} of greater than 0V. Current flow from source to drain stops and a depletion channel 208 forms due to an electric field from the drain voltage of V_{dd}. Because a non-zero gate voltage V_{mg} is applied to the metal gate material layer 142, an electric field 210 forms in the metal gate material layer 142 that releases electrons 206 to the source side of the channel region under the modulated gate 112 to reduce the electric field formed by the drain region 106 and reduces the depletion channel 208. The modulated gate 112 provides an inverse carrier for less channel depletion. A FinFET device within a 3-D structure can provide better gate control ability, so it is easier to drive the electron tunneling into the channel under the modulated gate 112 for reducing depletion near the drain side.

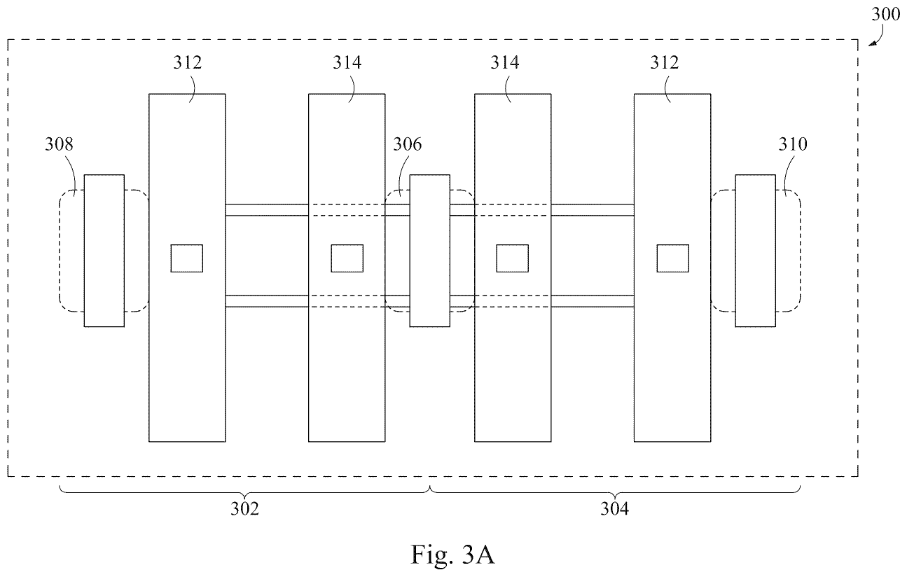

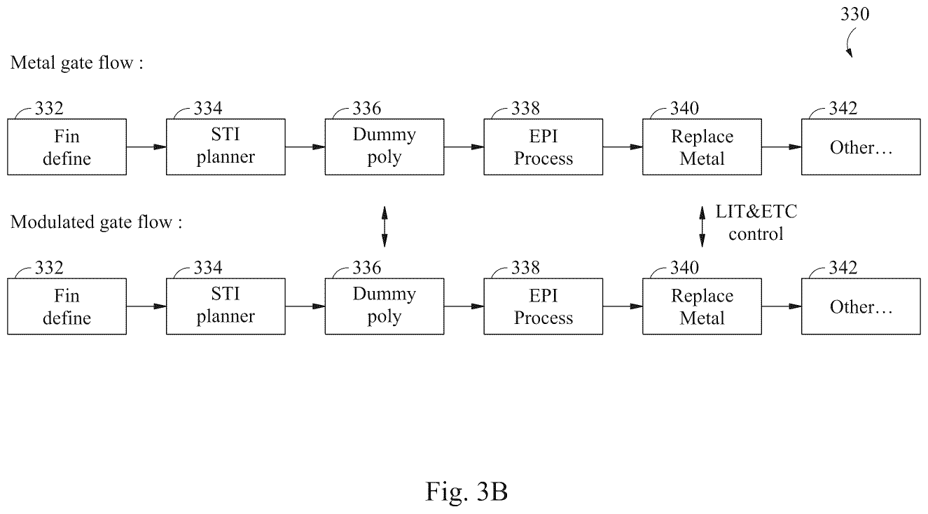

FIG. 3A is a top view of an example semiconductor structure 300 that includes multiple gate structures in series between a source region and a drain region, according to some embodiments. The example semiconductor structure 300 illustrates a configuration with symmetry by drain wherein a first high voltage device 302 and a second high voltage device 304 share a drain region 306, the first high voltage device 302 has a first source region 308, and the second high voltage device 304 has a second source region 310. In this example, each of the first high voltage device 302 and the second high voltage device 304 includes a control gate 312 and a secondary gate 314. By sharing the drain region 306, two high voltage devices can be formed using less surface area than two high voltage devices that do not share a drain region.

FIG. 3B is a flow chart depicting an example method 330 of fabricating a high voltage device that includes multiple gate structures in series between a source region and a drain region, according to some embodiments. It should be noted that method 330 may not produce a complete semiconductor device. The method 330 is merely an example, and is not intended to limit the present disclosure beyond what is explicitly recited in the claims. Additional steps may be provided before, during, and after example method 330, and some of the steps described can be moved, replaced, or eliminated for additional embodiments of example method 330. Further, it is understood that parts of the high voltage device may be fabricated by typical semiconductor technology process flow, and thus some processes are only briefly described herein.

At block 332, the example method 330 includes forming a fin on a substrate. In various embodiments, forming a fin includes forming an epitaxial layer over the substrate and patterning the epitaxial layer to form semiconductor fins (also referred to as fins). The epitaxial layer may be formed by a molecular beam epitaxy (MBE) process, a metalorganic chemical vapor deposition (MOCVD) process, and/or other suitable epitaxial growth processes. The fins may be fabricated using suitable processes including photolithography and etch processes.

At block 334, the example method 330 includes forming STI features on the substrate. In various embodiments, forming STI features includes forming STI features between fins.

At block 336, the example method 330 includes forming dummy gate structures on the fins. In various embodiments, forming dummy gate structures involve forming one or more sacrificial layers/features over the fin and patterning the one or more sacrificial layers/features to form a dummy gate structure on channel regions of the fins. When forming the dummy gates that are to be a modulated gate in a transistor, the forming includes removing the inter oxide (e.g., IL) and depositing a tunneling oxide layer, a trapping layer, and a control oxide layer under the polysilicon used for forming the dummy gates.

At block 338, the example method 330 includes forming the source and drain regions. In various embodiments, forming the source and drain regions involve forming gate sidewall spacers on sidewalls of the dummy gate structures, recessing the fins in the source drain/regions, and forming gate inner spacers before performing an epitaxial growth process to form the source and drain regions. In various embodiments, forming the source and drain regions also involve forming a CESL layer and an ILD layer around the source drain/regions.

At block 340, the example method 330 includes replacing the dummy gate structures with final gate structures. In the metal gate flow for control gates, this involves replacing the dummy gate structures with a high-K metal gate structure. In the trapping gate flow for modulated gates, this involves keeping the tunneling oxide layer, the trapping layer, and the control oxide layer, and replacing the dummy gate structures with a metal gate material layer.

At block 342, the example method 330 includes performing further fabrication. A semiconductor device may undergo further processing to form various features and regions known in the art.

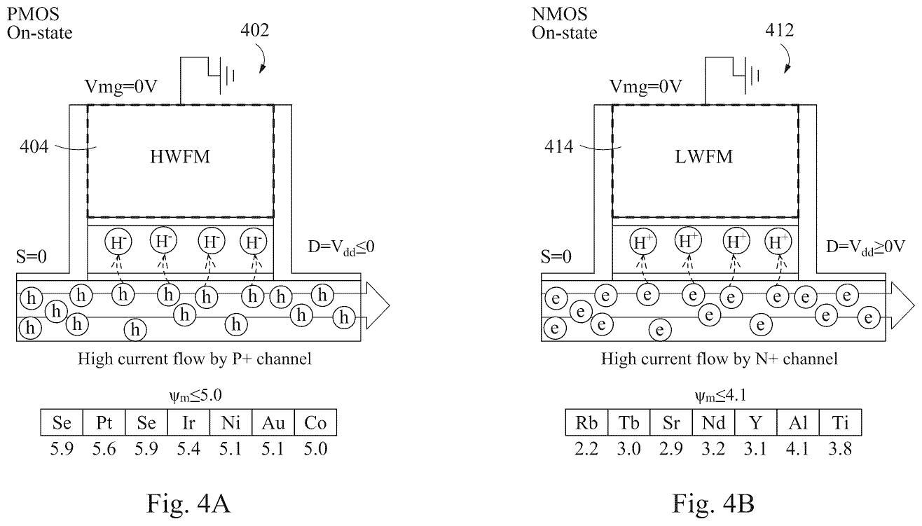

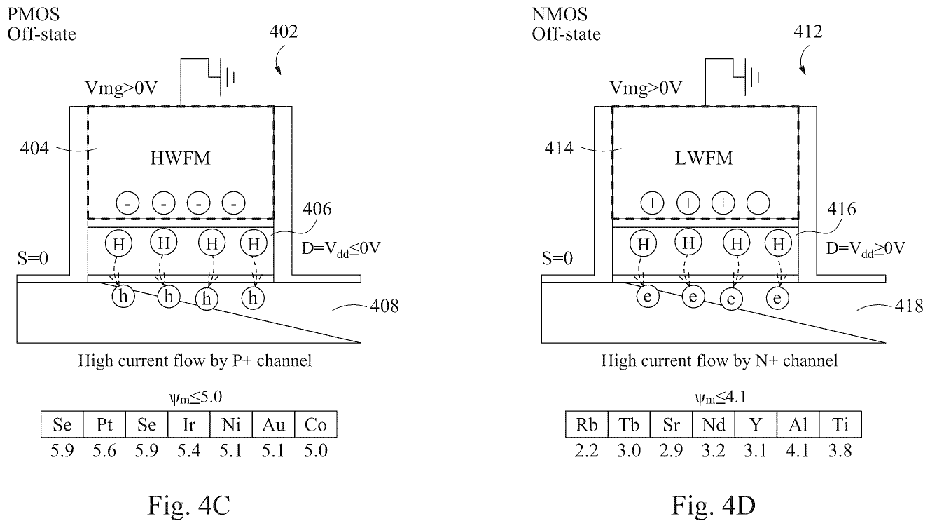

FIG. 4A depicts a cross-sectional view of an example modulated gate 402 for use in a high voltage PMOS high voltage FinFET device, and FIG. 4B depicts a cross-sectional view of an example modulated gate 412 for use in a high voltage NMOS high voltage FinFET device. In the example of FIG. 4A, during the on-state, the modulated gate 402 has a source voltage of around 0V, a drain voltage of V_{dd} less than or equal to 0V, and a gate voltage V_{mg} of around 0V. In the example of FIG. 4B, during the on-state, the modulated gate 412 has a source voltage of around 0V, a drain voltage of V_{dd} greater than or equal to 0V, and a gate voltage V_{mg} of around 0V. FIGS. 4A and 4B illustrate that performance of the high voltage FinFET device can be tuned based on the type of work function metal (WFM) used in the metal gate layer. In the example of FIG. 4A, the metal gate layer 404 includes a high work function metal (HWFM). In the example of FIG. 4B, the metal gate layer 414 includes a low work function metal (LWFM). The choice of WFM can reduce turn-on voltage. FIG. 4A illustrates that a PMOS high voltage FinFET device may benefit from a high work function metal (Ψm ≥5.0), such as Pt or Au. Other LWF metals that may be used include Se, Ir, Ni, and Co. FIG. 4B illustrates that an NMOS high voltage FinFET device may benefit from a low work function metal (Ψm≤4.1), such as Ti or Al. Other LWF metals that may be used include Rb, Tb, Sr, Nd, and Y.

FIG. 4C depicts a cross-sectional view of the example modulated gate 402 during an off-state, and FIG. 4D depicts a cross-sectional view of the example modulated gate 412 during an off-state. In the example of FIG. 4C, in the off-state, the modulated gate 402 has a source voltage of around 0V, a drain voltage of V_{dd} less than or equal to 0V, and a gate voltage V_{mg} less than or equal to 0V. In the off-state, the drain region has a higher voltage and stronger electric field than the source region and creates a depletion region 408 in a channel region between the source region and the drain region. During the off-state, the charge (e.g., hole) in the trapping layer 406 is released to the channel region under the modulated gate 402 to reduce the electric field and reduce the channel depletion region.

In the example of FIG. 4D, in the off-stated, the modulated gate 412 has a source voltage of around 0V, a drain voltage of V_{dd} greater than or equal to 0V, and a gate voltage V_{mg} greater than or equal to 0V. In the off-state, the drain region has a higher voltage and stronger electric field than the source region and creates a depletion region 418 in a channel region between the source region and the drain region. During the off-state, the charge (e.g., electron) in the trapping layer 416 is released to the channel region under the modulated gate 412 to reduce the electric field formed by the drain region and reduce the channel depletion region.

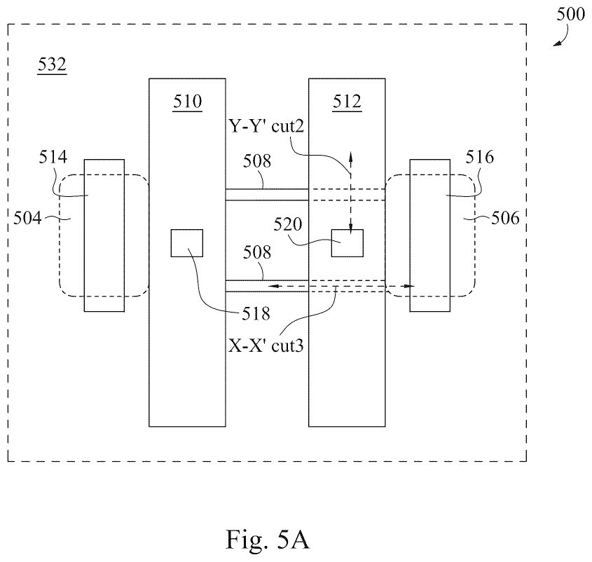

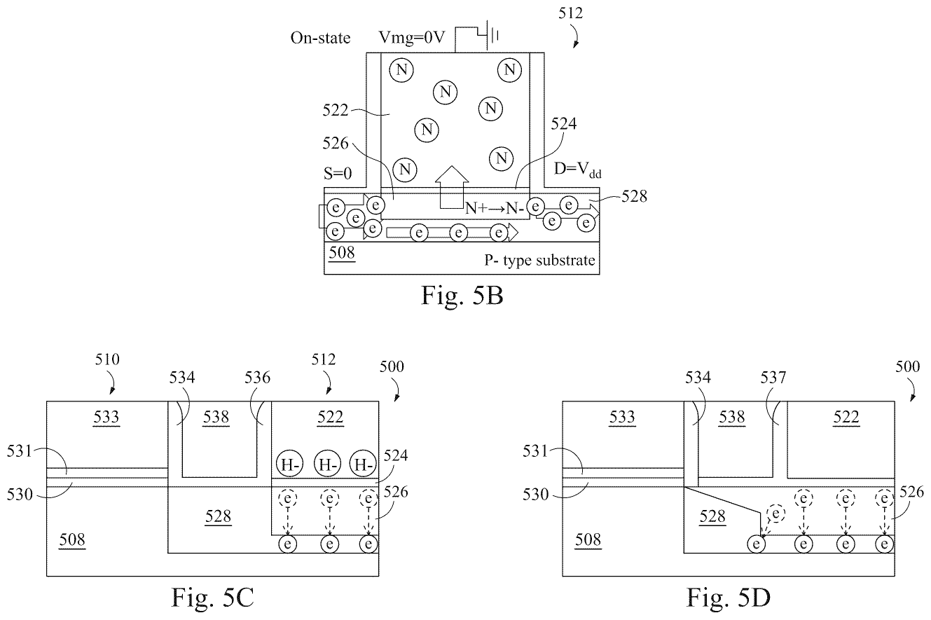

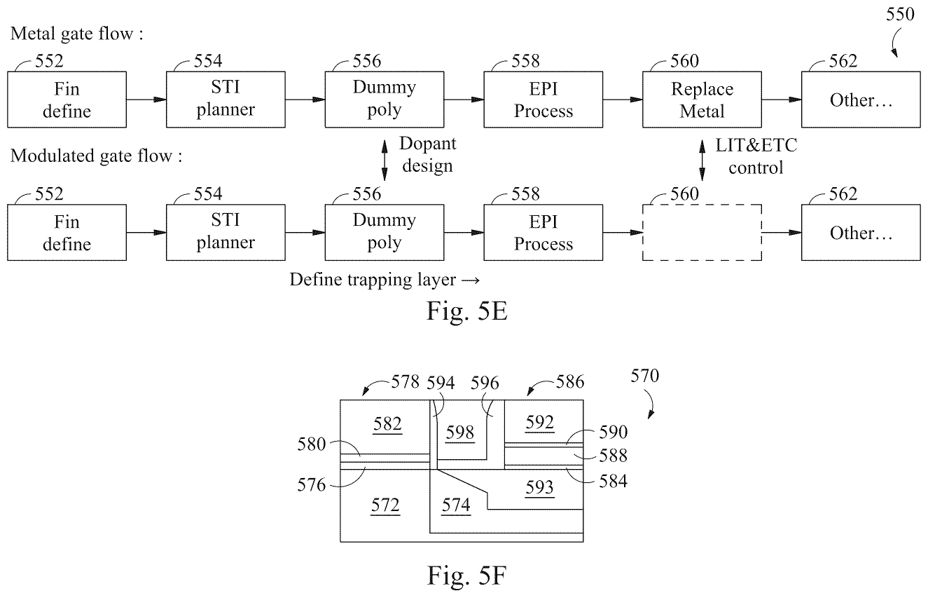

FIG. 5A is a top view of an example high voltage device 500 that includes multiple gate structures in series between a source region and a drain region, according to some embodiments. The example high voltage device 500 is a high voltage FinFET device for use in many high voltage applications such as amplifiers, including microwave power amplifiers, RF power amplifiers and audio power amplifiers, among others. The example high voltage device 500 includes a control gate 510 for turning the high voltage FinFET device on or off, and a secondary gate for improving the device's high voltage performance. In this example, the secondary gate is a depleted gate 512.

The example high voltage device 500 is formed on a substrate (e.g., p-type substrate) that includes a source region 504, a drain region 506, one or more fins 508 disposed between the source region 504 and the drain region 506, and a shallow trench isolation feature 532 for isolating various components. The high voltage device 500 further includes a control gate 510 disposed over the one or more fin 508 between the source region 504 and the drain region 506 and adjacent to the source region 504, and a depleted gate 512 disposed over the one or more fins 508 between the source region 504 and the drain region 506 and adjacent to the drain region 506. The high voltage device 500 also includes a source terminal 514 for the source region 504, a drain terminal 516 for the drain region 506, a control gate terminal 518 for the control gate 510, and a depleted gate terminal 520 for the depleted gate 512.

In various embodiments, the control gate 510 is similar to control gate 110 and includes similar components. In various embodiments, the example control gate 510 includes a fin 508 disposed between STI features, an IL disposed above the fin structure, an HK dielectric layer disposed above the IL, and a metal gate material layer disposed above the HK dielectric layer and disposed between a CESL and an interlayer dielectric layer (ILD0). In various embodiments, the fin structure comprises pure silicon (Si) or is slightly p-doped. In various embodiments, the doping of the slightly p-doped fin is less than 5×10¹⁶ parts per cm³.

The depleted gate 512 has a slightly doped gate structure. Use of the depleted gate 512 allows the distance between the drain region 506 and the control gate 510 to be shorter for high voltage applications therefore reducing substrate area needed to accommodate the high voltage device 500. Because the high voltage device 500 includes both a control gate 510 and a depleted gate 512, the high voltage device 500 includes a control channel under the control gate 510 and a depletion channel under the depleted gate 512.

FIG. 5B is a cross-sectional view of a depleted gate 512 along an X-X′ cut line 3. The depleted gate 512 includes an inter-trapping layer 522 comprising polysilicon that is slightly n-doped with an n-type dopant (e.g., phosphorus for NMOS and boron for PMOS), a tunneling oxide layer 524 below the inter-trapping layer 522, and in a highly doped portion 528 of a fin 508. In various embodiments, the inter-trapping layer 522 includes one or more of Si, C, N, Ge, Ga, Sb, In, As, or others. In various embodiments, the inter-trapping layer 522 includes approximately 1×10¹⁶ to approximately 5×10¹⁹ parts per cm³ of n-type dopant. The doping charge in the inter-trapping layer 522 is used to make electrons move into the substrate from the channel surface, so as to make slight doping depletion region 526 become slightly doped (N−). The slightly doping region makes diffusion bigger (larger depleted region between N−/N+ when in the off-state) so that breakdown voltage becomes larger. The depleted gate 512 has tunable charge injection that is based on the level of doping of the inter-trapping layer 522.

FIG. 5C is a cross-sectional view of the high voltage device 500 along a fin 508 between the control gate 510 and the depleted gate 512. Depicted are the fin 508 and the highly doped portion 528 of the fin 508, an IL 530 disposed above the fin 508 of the control gate 510, a HK dielectric layer 531 disposed above the IL 530, the metal gate material layer 533 for the control gate 510 disposed above the HK dielectric layer 531, the tunneling oxide layer 524 disposed above the slight doping depletion channel region 526 of the depleted gate 512, and the inter-trapping layer 522 disposed above the tunneling oxide layer 524. Also, depicted are a CESL 534 around the control gate 510, a contact CESL 536 around the depleted gate 512, and an ILD0 538 disposed between the CESL 534 and the CESL 536 and disposed above the highly doped portion 528 of the fin 508 that is between the control gate 510 and the depleted gate 512.

FIG. 5D is a cross-sectional view of the high voltage device 500 along a fin 508 between the control gate 510 and the depleted gate 512 with implant doping in the CESL 537 (material may use Si₄N₃) to extend the slight doping depletion channel region 526 under the CESL 537 to make the breakdown voltage even larger. Depicted are the fin 508 and the highly doped portion 528 of the fin 508, an IL 530 disposed above the fin 508 of the control gate 510, a HK dielectric layer 531 disposed above the IL 530, the metal gate material layer 533 for the control gate 510 disposed above the HK dielectric layer 531, the tunneling oxide layer 524 disposed above the slight doping depletion channel region 526 of the modulated gate 112, and the inter-trapping layer 522 disposed above the tunneling oxide layer 524. Also, depicted are a CESL 534 around the control gate 510, a contact CESL 537 around the depleted gate 512, and an ILD0 538 disposed between the CESL 534 and the CESL 536 and disposed above the highly doped portion 528 of the fin 508 that is between the control gate 510 and the depleted gate 512.

FIG. 5E is a flow chart depicting an example method 550 of fabricating a high voltage device that includes multiple gate structures in series between a source region and a drain region, according to some embodiments. It should be noted that method 550 may not produce a complete semiconductor device. The method 550 is merely an example, and is not intended to limit the present disclosure beyond what is explicitly recited in the claims. Additional steps may be provided before, during, and after example method 550, and some of the steps described can be moved, replaced, or eliminated for additional embodiments of example method 550. Further, it is understood that parts of the high voltage device may be fabricated by typical semiconductor technology process flow, and thus some processes are only briefly described herein.

At block 552, the example method 550 includes forming a fin on a substrate. In various embodiments, forming a fin includes forming an epitaxial layer over the substrate and patterning the epitaxial layer to form semiconductor fins (also referred to as fins). The epitaxial layer may be formed by a molecular beam epitaxy (MBE) process, a metalorganic chemical vapor deposition (MOCVD) process, and/or other suitable epitaxial growth processes. The fins may be fabricated using suitable processes including photolithography and etch processes.

At block 554, the example method 550 includes forming STI features on the substrate. In various embodiments, forming STI features includes forming STI features between fins.

At block 556, the example method 550 includes forming dummy gate structures on the fins. In various embodiments, forming dummy gate structures involve forming one or more sacrificial layers/features over the fin and patterning the one or more sacrificial layers/features to form a dummy gate structure on channel regions of the fins. When forming the dummy gates that are to become a depleted gate in a transistor, the forming includes removing the inter oxide (e.g., IL), depositing a tunneling oxide layer, forming polysilicon structures for the dummy gates over the tunneling oxide layer, and doping the polysilicon structure. In various embodiments, the polysilicon structures are doped with n-type dopants.

At block 558, the example method 550 includes forming the source and drain regions. In various embodiments, forming the source and drain regions involve forming gate sidewall spacers on sidewalls of the dummy gate structures, recessing the fins in the source drain/regions, and forming gate inner spacers before performing an epitaxial growth process to form the source and drain regions. In various embodiments, forming the source and drain regions also involve forming a CESL layer and an ILD layer around the source drain/regions.

At block 560, the example method 550 includes replacing the dummy gate structures with final gate structures. In the metal gate flow for control gates, this involves replacing the dummy gate structures with a high-K metal gate structure. In the trapping gate flow for depleted gates, this involves keeping the tunneling oxide layer and the doped polysilicon structures.

At block 562, the example method 550 includes performing further fabrication. A semiconductor device may undergo further processing to form various features and regions known in the art.

FIG. 5F is a cross-sectional view of an example high voltage device 570 (e.g., along and between X-X′ cut line 1 and X-X′ cut line 2 of FIG. 1A) that includes multiple gate structures in series between a source region and a drain region, according to some embodiments. FIG. 5F illustrates that a slight doping depletion channel region and an extension of the slight doping depletion channel region resulting from a doped CESL can be applied to a high voltage device that includes a depleted gate as a secondary gate.

Depicted are a fin 572 and a highly doped portion 574 of the fin 572, an IL 576 disposed above the fin 572 of a control gate 578, a the HK dielectric layer 580 disposed above the IL 576, a metal gate material layer 582 for the control gate 578 disposed above the HK dielectric layer 580, a tunneling oxide layer 584 disposed above the highly doped portion 574 of the modulated gate 586, a trapping layer 588 disposed above the tunneling oxide layer 584, a control oxide layer 590 disposed above the trapping layer 588, a metal gate material layer 592 of the modulated gate 586 disposed above the control oxide layer 590, and a slight doping depletion channel region 593 under the tunneling oxide layer 584 and in the highly doped portion 574 of the fin 572. Doping can be used to make the slight doping depletion channel region 593 become slightly doped (N-). Slight doping can make diffusion larger so that breakdown voltage becomes larger. Also, depicted are a CESL 594 around the control gate 578, a contact CESL 596 around the modulated gate 586, and an ILD0 598 disposed between the CESL 594 and the contact CESL 596 and disposed above the highly doped portion 574 of the fin 572 that is between the control gate 578 and the modulated gate 586. With implant doping in the CESL 596, the slight doping depletion channel region 593 under the CESL 596 can be extended to make the breakdown voltage for the high voltage device 570 even larger.

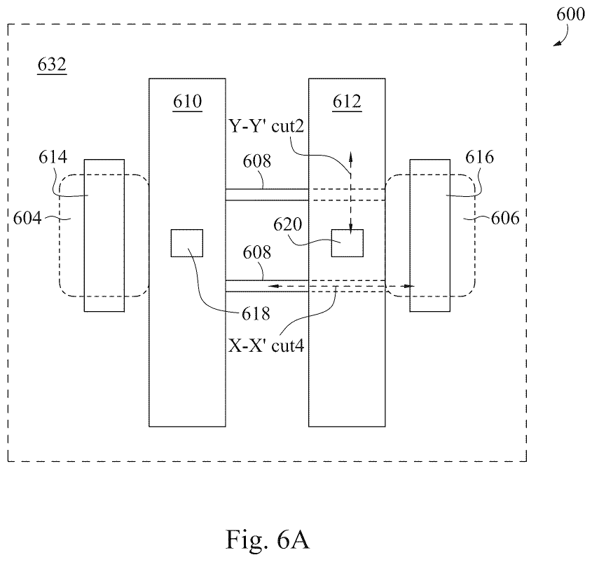

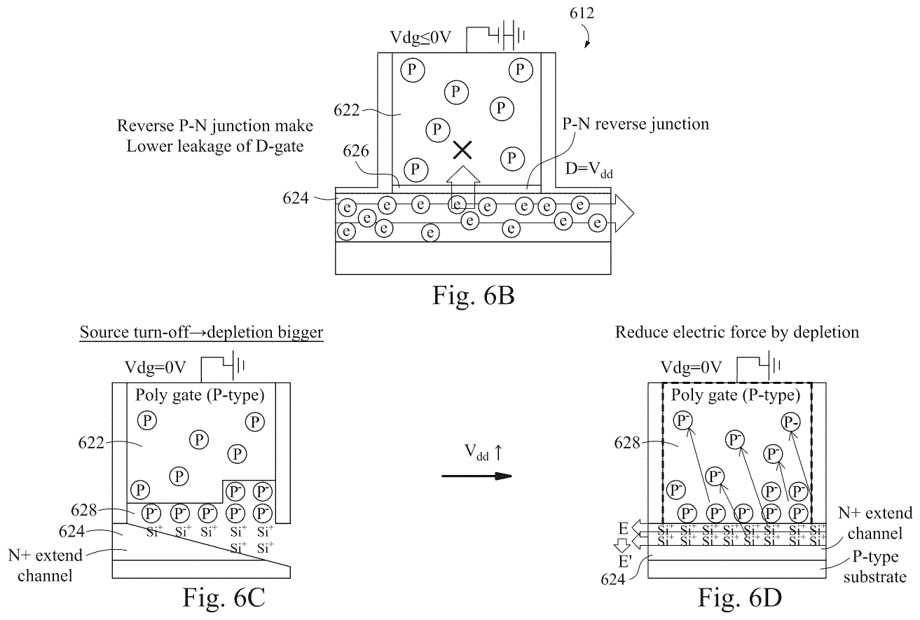

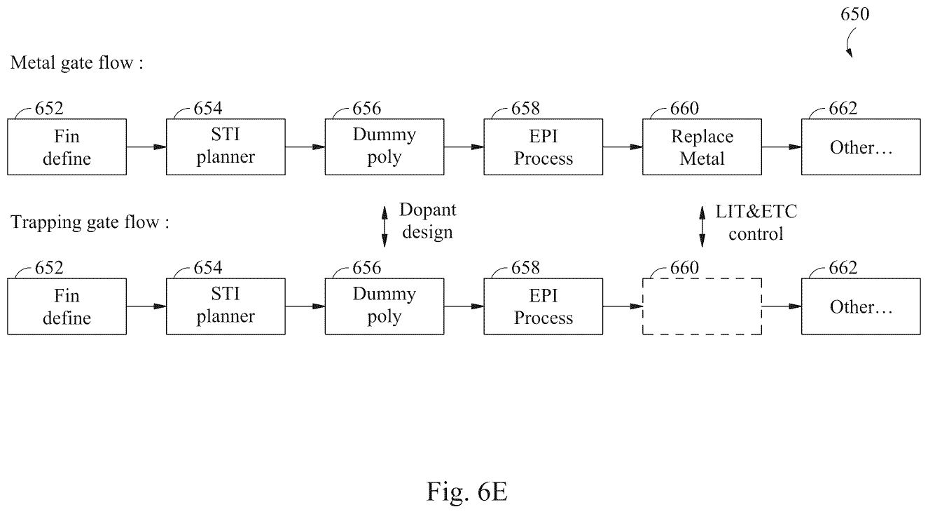

FIG. 6A is a top view of an example high voltage device 600 that includes multiple gate structures in series between a source region and a drain region, according to some embodiments. The example high voltage device 600 is a high voltage FinFET device for use in many high voltage applications such as amplifiers, including microwave power amplifiers, RF power amplifiers and audio power amplifiers, among others. The example high voltage device 600 includes a control gate 610 for turning the high voltage FinFET device on or off, and a secondary gate for improving the device's high voltage performance. In this example, the secondary gate is an anti-type depleted gate 612.

The example high voltage device 600 is formed on a substrate (e.g., p-type substrate) that includes a source region 604, a drain region 606, one or more fins 608 disposed between the source region 604 and the drain region 606, and a shallow trench isolation feature 632 for isolating various components. The high voltage device 600 further includes a control gate 610 disposed over the one or more fins 608 between the source region 604 and the drain region 606 and adjacent to the source region 604, and an anti-type depleted gate 612 disposed over the one or more fins 608 between the source region 604 and the drain region 606 and adjacent to the drain region 606. The high voltage device 600 also includes a source terminal 614 for the source region 604, a drain terminal 616 for the drain region 606, a control gate terminal 618 for the control gate 610, and an anti-type gate terminal 620 for the anti-type depleted gate 612.

In various embodiments, the control gate 610 is similar to control gate 110 and includes similar components. In various embodiments, the example control gate 610 includes a fin 608 disposed between STI features 632, an IL disposed above the fin structure, an HK dielectric layer disposed above the IL, and a metal gate material layer disposed above the HK dielectric layer and disposed between a CESL and an interlayer dielectric layer (ILD0). In various embodiments, the fin structure comprises pure silicon (Si) or is slightly p-doped. In various embodiments, the doping of the slightly p-doped fin is less than 5×10¹⁶ parts per cm³.

The anti-type depleted gate 612 has a slightly doped structure. The Use of the anti-type depleted gate 612 allows the distance between the drain region 606 and the control gate 610 to be shorter for high voltage applications therefore reducing substrate area needed to accommodate the high voltage device 600. Because the high voltage device 600 includes both a control gate 610 and an anti-type depleted gate 612, the high voltage device 600 includes a control channel (not shown) under the control gate 610 and an anti-type channel under the anti-type depleted gate 612.

FIG. 6B is a cross-sectional view of an anti-type depleted gate 612 along an X-X′ cut line 4 in an on-state. FIGS. 6C and 6D are cross-sectional views of an anti-type depleted gate 612 along the X-X′ cut line 4 in an off-state. The anti-type depleted gate 612 includes a doped polysilicon region 622 that is doped with p-type dopants (e.g., 5×10¹⁶), does not have an oxide layer below the polysilicon region 622, and includes a highly doped portion 624 in a channel region of a fin, wherein a P-N reverse junction 626 is formed between the polysilicon region 622 and the highly doped portion 624. In various embodiments, the p-type dopant includes approximately 1×10¹⁶ to approximately 5×10¹⁹ parts per cm³. The P-N reverse junction 626 causes a depletion region 628 in the channel region under the anti-type depleted gate 612. In an off-state, the depletion region 628 gets larger as illustrated in FIGS. 6C and 6D. An increase in drain voltage V_{dd} can cause further increase in the size of the depletion region 628 by creating a greater electric field. The anti-type depleted gate 612 has tunable charge injection that is based on the level of the drain voltage V_{dd}.

FIG. 6E is a flow chart depicting an example method 650 of fabricating a high voltage device that includes multiple gate structures in series between a source region and a drain region, according to some embodiments. It should be noted that method 650 may not produce a complete semiconductor device. The method 650 is merely an example, and is not intended to limit the present disclosure beyond what is explicitly recited in the claims. Additional steps may be provided before, during, and after example method 650, and some of the steps described can be moved, replaced, or eliminated for additional embodiments of example method 650. Further, it is understood that parts of the high voltage device may be fabricated by typical semiconductor technology process flow, and thus some processes are only briefly described herein.

At block 652, the example method 650 includes forming a fin on a substrate. In various embodiments, forming a fin includes forming an epitaxial layer over the substrate and patterning the epitaxial layer to form semiconductor fins (also referred to as fins). The epitaxial layer may be formed by a molecular beam epitaxy (MBE) process, a metalorganic chemical vapor deposition (MOCVD) process, and/or other suitable epitaxial growth processes. The fins may be fabricated using suitable processes including photolithography and etch processes.

At block 654, the example method 650 includes forming STI features on the substrate. In various embodiments, forming STI features includes forming STI features between fins.

At block 656, the example method 650 includes forming dummy gate structures on the fins. In various embodiments, forming dummy gate structures involve forming one or more sacrificial layers/features over the fin and patterning the one or more sacrificial layers/features to form a dummy gate structure on channel regions of the fins. When forming the dummy gates that are to become an anti-type depleted gate in a transistor, the forming includes removing the inter oxide (e.g., IL), forming polysilicon structures for the dummy gates without an oxide layer, and doping the polysilicon structure. In various embodiments, the polysilicon structures are doped with p-type dopants.

At block 658, the example method 650 includes forming the source and drain regions. In various embodiments, forming the source and drain regions involve forming gate sidewall spacers on sidewalls of the dummy gate structures, recessing the fins in the source drain/regions, and forming gate inner spacers before performing an epitaxial growth process to form the source and drain regions. In various embodiments, forming the source and drain regions also involve forming a CESL layer and an ILD layer around the source drain/regions.

At block 660, the example method 650 includes replacing the dummy gate structures with final gate structures. In the metal gate flow for control gates, this involves replacing the dummy gate structures with a high-K metal gate structure. In the trapping gate flow for anti-type depleted gates, this involves keeping the doped polysilicon structures without the oxide layer.

At block 662, the example method 650 includes performing further fabrication. A semiconductor device may undergo further processing to form various features and regions known in the art.

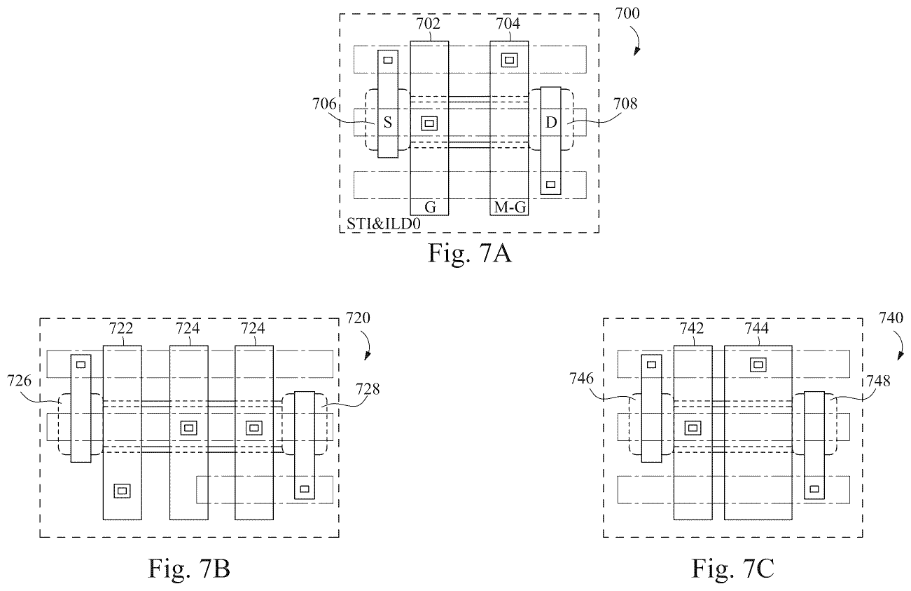

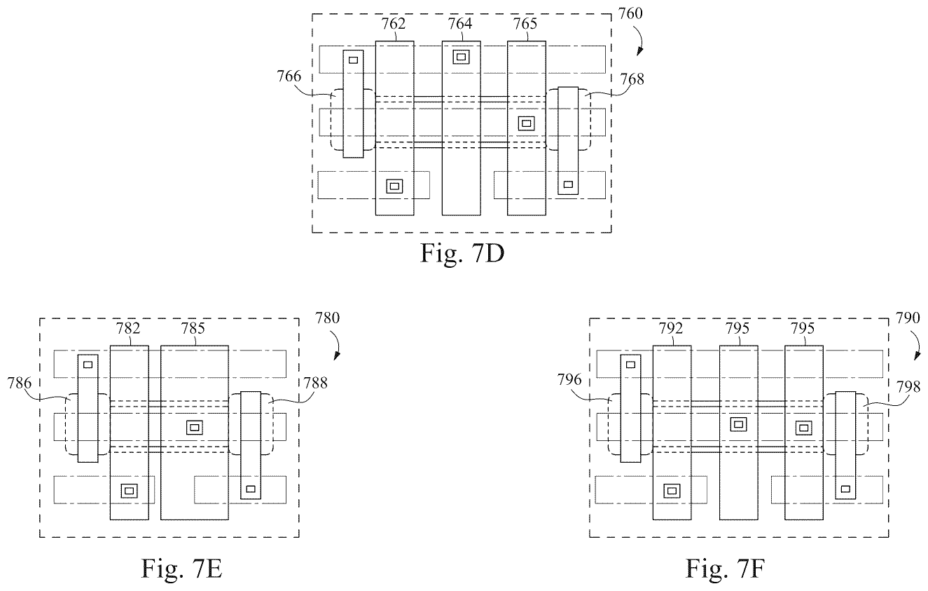

FIGS. 7A-7F are top views of example high voltage devices that include multiple gate structures in series between a source region and a drain region, according to some embodiments. In these examples, high voltage devices with vary numbers and/or relative sizes of control gates, modulated gates, and/or depleted gates are illustrated.

FIG. 7A is a top view of an example high voltage device 700 that includes multiple gate structures in series between a source region and a drain region, according to some embodiments. The example high voltage device 700 includes a control gate 702, a modulated gate 704, a source 706, and a drain 708. In this example, the control gate 702 and the modulated gate 704 have the same width. In various embodiments, the width of the control gate 702 is 20 nm and the width of the modulated gate 704 is 20 nm.

FIG. 7B is a top view of an example high voltage device 720 that includes multiple gate structures in series between a source region and a drain region, according to some embodiments. The example high voltage device 720 includes a control gate 722, a plurality of modulated gates 724, a source 726, and a drain 728. In this example, the control gate 722 and each of the modulated gates 724 have the same width. In various embodiments, the width of the control gate 722 is 20 nm and the width of the modulated gates 724 is 20 nm.

FIG. 7C is a top view of an example high voltage device 740 that includes multiple gate structures in series between a source region and a drain region, according to some embodiments. The example high voltage device 740 includes a control gate 742, a modulated gate 744, a source 746, and a drain 748. In this example, the width of the modulated gate 744 is larger than the width of the control gate 742. In various embodiments, the width of the modulated gate 744 may be up to 15 times the width of the control gate 742. In various embodiments, the width of the control gate 742 is 20 nm and the width of the modulated gate 744 is 240 nm.

FIG. 7D is a top view of an example high voltage device 760 that includes multiple gate structures in series between a source region and a drain region, according to some embodiments. The example high voltage device 760 includes a control gate 762, a modulated gate 764, a depleted gate 765, a source 766, and a drain 768. In this example, each of the control gate 762, the modulated gates 764, and the depleted gate 765 have the same width. In various embodiments, the width of the control gate 762 is 20 nm, the width of the modulated gates 764 is 20 nm, and the width of the depleted gate 765 is 20 nm.

FIG. 7E is a top view of an example high voltage device 780 that includes multiple gate structures in series between a source region and a drain region, according to some embodiments. The example high voltage device 780 includes a control gate 782, a depleted gate 785, a source 786, and a drain 788. In this example, the width of the depleted gate 785 is larger than the width of the control gate 782. In various embodiments, the width of the depleted gate 785 may be up to 15 times the width of the control gate 782. In various embodiments, the width of the control gate 782 is 20 nm and the width of the depleted gate 785 is 240 nm.

FIG. 7F is a top view of an example high voltage device 790 that includes multiple gate structures in series between a source region and a drain region, according to some embodiments. The example high voltage device 790 includes a control gate 792, a plurality of depleted gates 795, a source 796, and a drain 798. In this example, the control gate 792 and each of the depleted gates 795 have the same width. In various embodiments, the width of the control gate 792 is 20 nm, the width of the plurality of depleted gates 795 is 20 nm.

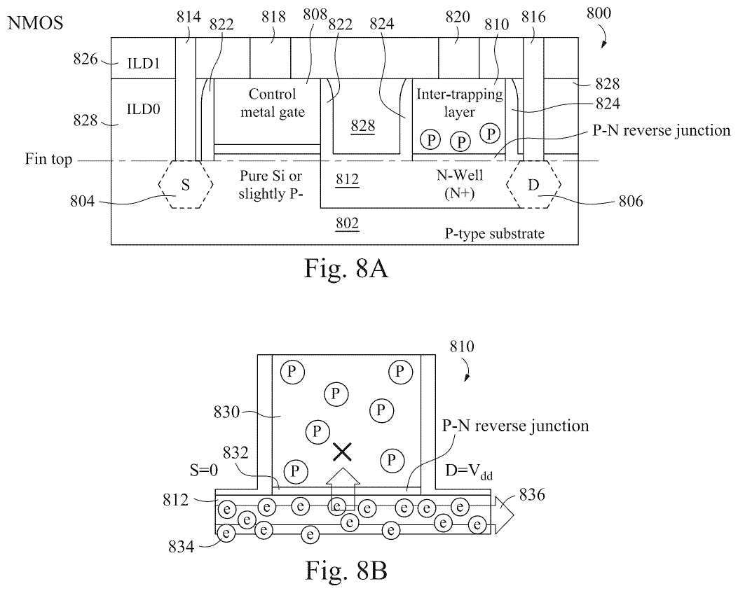

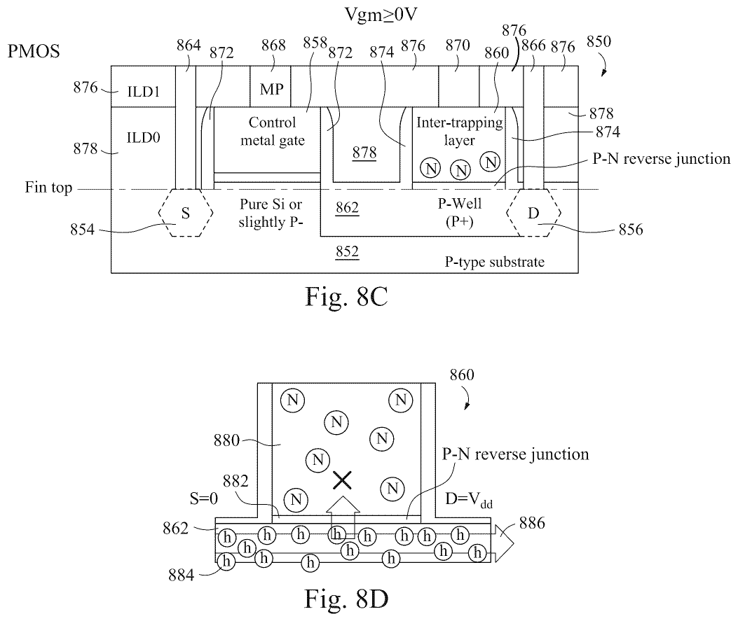

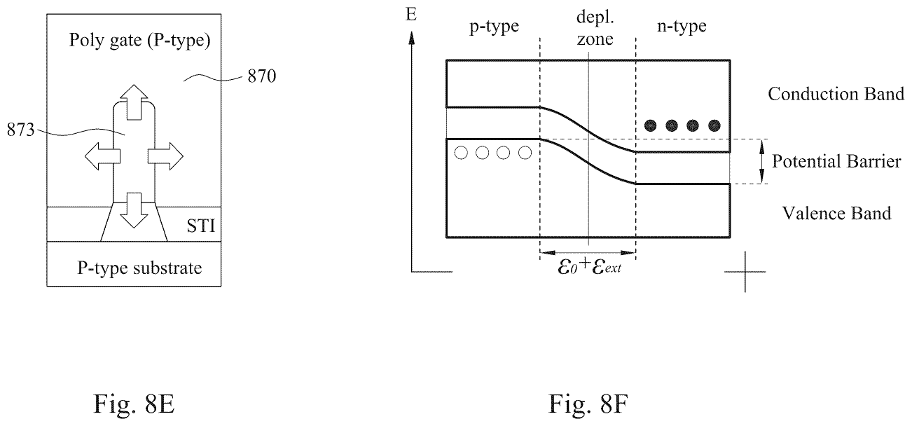

FIG. 8A is a cross-sectional view of an example NMOS high voltage device 800 that includes multiple gate structures in series between a source region and a drain region, according to some embodiments. The NMOS high voltage device 800 includes a fin 802 formed in a substrate (e.g., p-type substrate) that includes a source region 804, a drain region 806, a control gate 808 disposed between the source region 804 and the drain region 806 adjacent to the source region 804, an anti-type depleted gate 810 disposed between the source region 804 and the drain region 806 and adjacent to the drain region 806, and an N-well 812 formed between an end of the control gate 808 and the drain region 806 and under the anti-type depleted gate 810. The NMOS high voltage device 800 further includes a source terminal 814 for the source region 804, a drain terminal 816 for the drain region 806, a control gate terminal 818 for the control gate 808, and a depleted gate terminal 820 for the anti-type depleted gate 810. The control gate 808 is bounded by gate spacers 822 (e.g., a CESL), and the anti-type depleted gate 810 is bounded by gate spacers 824. An ILD0 layer 826 surrounds the control gate 808, anti-type depleted gate 810, gate spacers 822 and gate spacers 824. An ILD1 layer 828 is disposed above the ILD0 layer 826. In operation, a ground voltage level is applied at the source terminal 814, and a voltage less than or equal to zero is applied at the depleted gate terminal 820. A control signal for turning the NMOS high voltage device 800 on or off is applied at the control gate terminal 818, while the anti-type depleted gate 810 is not switched.

FIG. 8B is a cross-sectional drawing of the anti-type depleted gate 810. The anti-type depleted gate 810 includes an inter-trapping layer 830 comprising polysilicon material that is doped with P-type doping of approximately 1×10¹⁶ to approximately 5×10¹⁹ parts per cm³. The inter-trapping layer 830 is disposed above the n-well 812 with a P-N reverse junction 832 formed therebetween. During the on-state of the anti-type depleted gate 810, electrons 834 flow in the direction 836 of the source terminal 814 to the drain terminal 816, but do not cross the P-N reverse junction 832 to the inter-trapping layer 830.

FIG. 8C is a cross-sectional view of an example PMOS high voltage device 850. The PMOS high voltage device 850 includes a fin 852 formed in a substrate (e.g., p-type substrate) that includes a source region 854, a drain region 856, a control gate 858 disposed between the source region 854 and the drain region 856 and adjacent to the source region 854, an anti-type depleted gate 860 disposed between the source region 854 and the drain region 856 and adjacent to the drain region 856, and an N-well 862 formed between an end of the control gate 858 and the drain region 856 and under the anti-type depleted gate 860. The PMOS high voltage device 850 further includes a source terminal 864 for the source region 854, a drain terminal 866 for the drain region 856, a control gate terminal 868 for the control gate 858, and a depleted gate terminal 870 for the anti-type depleted gate 860. The control gate 858 is bounded by gate spacers 872 (e.g., a CESL), and the anti-type depleted gate 860 is bounded by gate spacers 874. An ILD0 layer 876 surrounds the control gate 858, anti-type depleted gate 860, gate spacers 872 and gate spacers 874. An ILD1 layer 878 is disposed above the ILD0 layer 876. In operation, a ground voltage level is applied at the source terminal 864, and a voltage greater than or equal to zero is applied at the depleted gate terminal 870. A control signal for turning the PMOS high voltage device 850 on or off is applied at the control gate terminal 868, while the anti-type depleted gate 860 is not switched.

FIG. 8D is a cross-sectional drawing of the anti-type depleted gate 860. The anti-type depleted gate 860 includes an inter-trapping layer 880 comprising polysilicon material that is doped with N-type doping of approximately 1×10¹⁶ to approximately 5×10¹⁹ parts per cm³. The inter-trapping layer 880 is disposed above the n-well 862 with a P-N reverse junction 882 formed therebetween. During the on-state of the anti-type depleted gate 860 Holes 884 flow in the direction 886 of the source terminal 864 to the drain terminal 866, but do not cross the P-N reverse junction 882 to the inter-trapping layer 880.

FIG. 8E is a cross-sectional view of an anti-type depleted gate 860 around a channel layer 873, along a Y-Y′ cut line of a high voltage device, and FIG. 8F is a diagram illustrating electrical properties of the anti-type depleted gate 860. In some embodiments, the channel layer 873 under the anti-type depleted gate 860 may be formed from middle bandgap material, such as Si, Ge, GaA, and others. In the example embodiment, the depleted gate is formed with Wide bandgap material, such as SiC, GaN, and others. By using wide bandgap material for the channel layer 873, 4-aspect depletion can be achieved using the depleted gate structure, as opposed to 1-aspect depletion with middle bandgap material. The wide bandgap material makes the P-N barrier become bigger, as illustrated in FIG. 8F, which can lead to better breakdown voltage performance for the high voltage device.

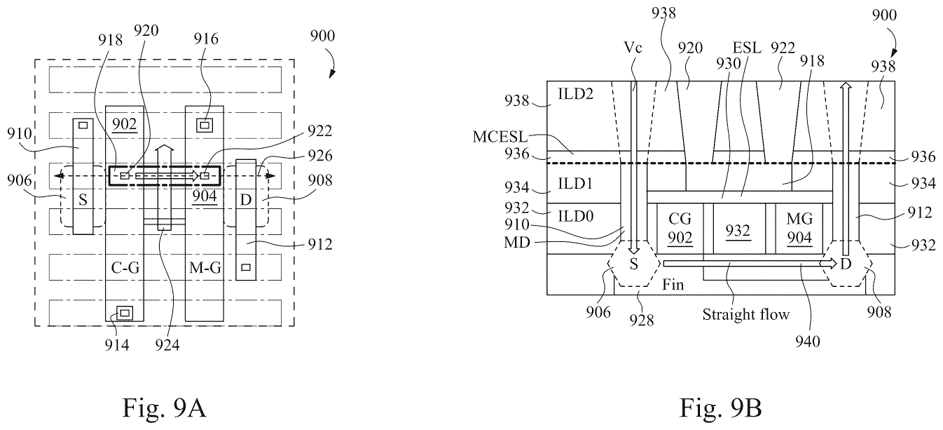

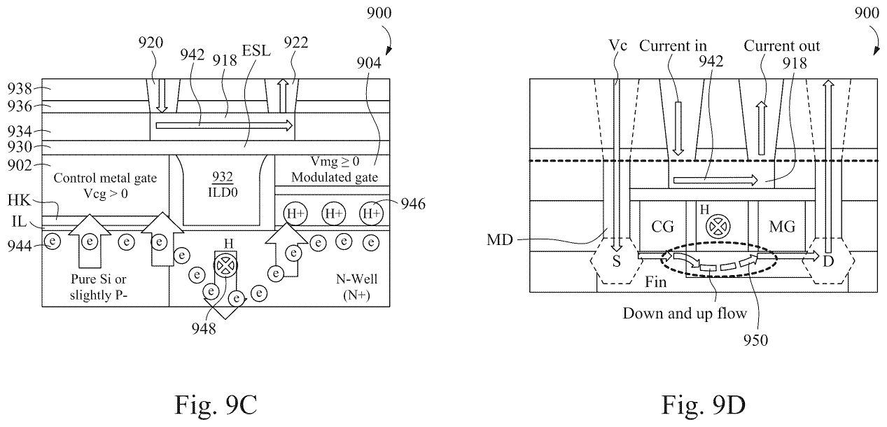

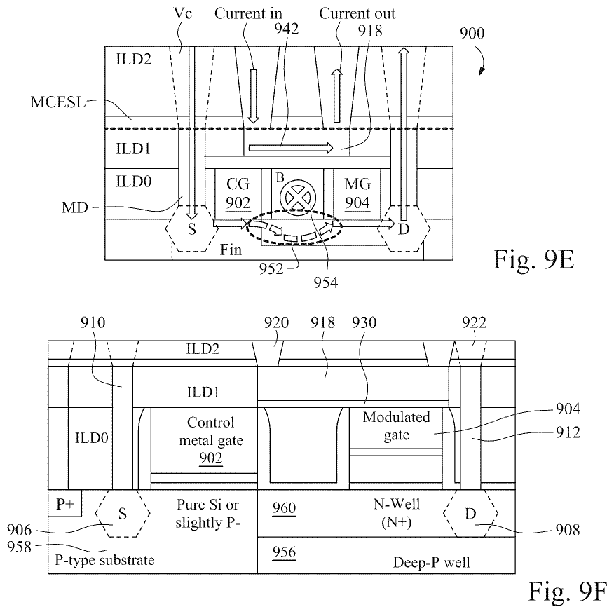

FIG. 9A is a top view of an example high voltage device 900 that includes multiple gate structures in series between a source region and a drain region, according to some embodiments. The example high voltage device 900 includes a control gate 902 (e.g., control gate 110), a modulated gate 904 (e.g., modulated gate 112), a source region 906, and a drain region 908. The control gate 902 and the modulated gate 904 are disposed between the source region 906 and the drain region 908, with the control gate 902 disposed closer to the source region 906 and the modulated gate 904 disposed closer to the drain region 908. The high voltage device 900 also includes a source terminal 910 for the source region 906, a drain terminal 912 for the drain region 908, a control gate terminal 914 for the control gate 902, and a modulated gate terminal 916 for the modulated gate 904. A metal line 918 is coupled to a first VIA 920 above the control gate 902 and a second VIA 922 above the modulated gate 904. The metal line 918 is disposed above a channel region between the control gate 902 and the modulated gate 904. When a current is applied between the first VIA 920 and the second VIA 922, a magnetic field 924 is induced across a channel between the control gate 902 and the modulated gate 904.

FIG. 9B is a cross-sectional view of the high voltage device 900 along a cut line 926 in FIG. 9A. The example high voltage device 900 includes a fin structure 928 with the source region 906 and the drain region 908 disposed in the fin structure 928. The control gate 902 and the modulated gate 904 are disposed between the source region 906 and the drain region 908, with the control gate 902 disposed closer to the source region 906 and the modulated gate 904 disposed closer to the drain region 908. Also depicted are the source terminal 910 for the source region 906, a drain terminal 912 for the drain region 908, a metal line 918 is coupled to the first VIA 920 above the control gate 902 and a second VIA 922 above the modulated gate 904, is separated from the control gate 902 and the modulated gate 904 by an etch stop layer (ESL 930), and is disposed above a channel region between the control gate 902 and the modulated gate 904. The high voltage device 900 further includes an ILD0 layer 932, an ILD1 layer 934, a metal contact etch stop layer (MCESL 936), and an ILD2 layer 938. When the high voltage device 900 is in the on-state, a current will flow, in a straight flow 940, between the source region 906 and the drain region 908.

FIG. 9C is a cross-sectional view of the high voltage device 900 during an on-state with a current flow 942 through the metal line 918. The inversion charge from the control gate 902 causes the electron carrier 944 to stay near the bottom surface of the control gate 902 in the channel under the control gate 902. The positive ions 946 in the modulated gate 904 causes the electron carrier 944 to stay near the bottom surface of the modulated gate 904 in the channel under the modulated gate 904. The current flow 942 through the metal line 918 induces an electric field 948 that forces the electron carrier 944 down and away from the ILD0 layer 932.

FIG. 9D is another cross-sectional view of the high voltage device 900 during an on-state. This figure illustrates that carrier path 950 can be made longer due to Lorentz force generated as a result of current flow 942 through the metal line 918.

FIG. 9E is another cross-sectional view of the high voltage device 900 during an on-state. This figure illustrates that a carrier path 952 can be made even longer due to Lorentz force generated as a result of current flow 942 through the metal line 918 and a magnetic field resulting from soft magnetic material 954 (e.g., Fe, Ni, Mo, Co, Zn, or others) formed in the ILD0 layer 932 between the control gate 902 and the modulated gate 904.

FIG. 9F is a cross-sectional view of another embodiment of the high voltage device 900 along the cut line 926. In this example, the high voltage device 900 includes the components described with respect to FIGS. 9A and 9B, but also includes a deep P-well 956 formed in the substrate 958 underneath the N-well 960. The deep P-well 956 provides a bottom boundary for a carrier path (e.g., carrier path 950 or carrier path 952) and forces the carrier path to curve upward in the drain region 908. Ordinary Magnetoresistance (ORM) makes the electron path increase thereby causing larger breakdown voltage (BV) for the high voltage device 900. The Reverse P-N junction between the N-well 960 and the deep P-well 956 can make the electrons return to the N+ channel.

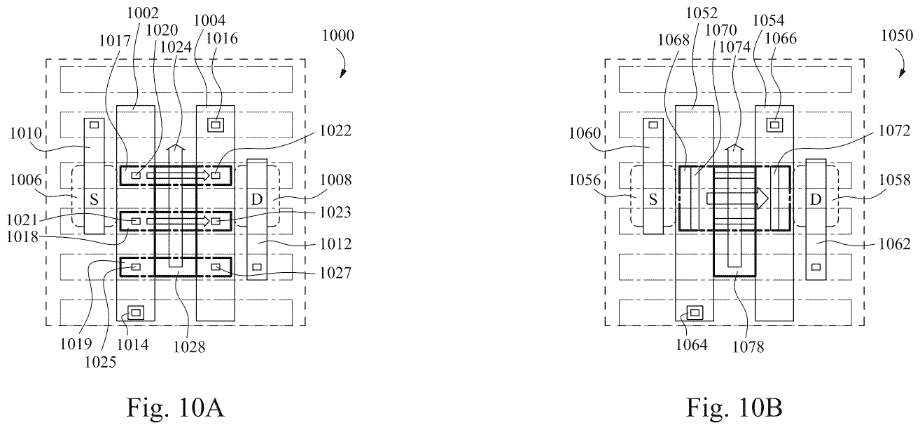

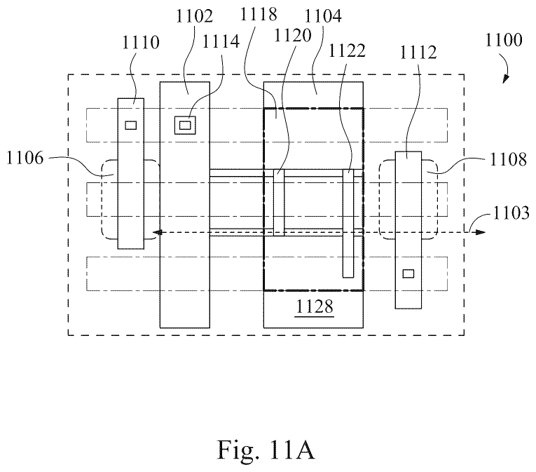

FIG. 10A is a top view of an example high voltage device 1000 that includes multiple gate structures in series between a source region and a drain region, according to some embodiments. The example high voltage device 1000 includes a control gate 1002, a modulated gate 1004, a source region 1006, and a drain region 1008. The control gate 1002 and the modulated gate 1004 are disposed between the source region 1006 and the drain region 1008, with the control gate 1002 disposed closer to the source region 1006 and the modulated gate 1004 disposed closer to the drain region 1008. The high voltage device 1000 also includes a source terminal 1010 for the source region 1006, a drain terminal 1012 for the drain region 1008, a control gate terminal 1014 for the control gate 1002, and a modulated gate terminal 1016 for the modulated gate 1004. A first metal line 1017 is coupled to a first VIA 1020 above the control gate 1002 and a second VIA 1022 above the modulated gate 1004. A second metal line 1018 is coupled to another first VIA 1021 above the control gate 1002 and another second VIA 1023 above the modulated gate 1004. A third metal line 1019 is coupled to another first VIA 1025 above the control gate 1002 and another second VIA 1027 above the modulated gate 1004. The metal lines 1017, 1018, 1019 are disposed above channel regions between the control gate 1002 and the modulated gate 1004. When currents are applied between the first VIA 1020 and the second VIA 1022, the first VIA 1021 and the second VIA 1023, and the first VIA 1025 and the second VIA 1027, a magnetic field 1024 is induced across channels between the control gate 1002 and the modulated gate 1004.

The magnetic field 1024 is enhanced and can be stronger than the magnetic field 924 because of contributions to the magnetic field 1024 by the plurality (three in this example) of metal lines (e.g., first metal line 1017, second metal line 1018, and third metal line 1019). The magnetic field 1024 is further enhanced and made stronger by the use of soft magnetic material 1028 (e.g., Fe, Ni, Mo, Co, Zn, or others) included in the interlayer dielectric material between the control gate 1002 and the modulated gate 1004. A carrier path between the control gate 1002 and the modulated gate 1004 can be made longer by the magnetic field 1024.

FIG. 10B is a top view of an example high voltage device 1050 that includes multiple gate structures in series between a source region and a drain region, according to some embodiments. The example high voltage device 1050 includes a control gate 1052, a modulated gate 1054, a source region 1056, and a drain region 1058. The control gate 1052 and the modulated gate 1054 are disposed between the source region 1056 and the drain region 1058, with the control gate 1052 disposed closer to the source region 1056 and the modulated gate 1054 disposed closer to the drain region 1058. The high voltage device 1050 also includes a source terminal 1060 for the source region 1056, a drain terminal 1062 for the drain region 1058, a control gate terminal 1064 for the control gate 1052, and a modulated gate terminal 1066 for the modulated gate 1054. A metal line 1068 is coupled to a first VIA 1070 above the control gate 1052 and a second VIA 1072 above the modulated gate 1054. The metal line 1068 is disposed above channel region between the control gate 1052 and the modulated gate 1054. The metal line 1068 is substantially wider than the metal line 918 (e.g., greater than 1.5 times wider). When currents are applied between the first VIA 1070 and the second VIA 1072, a magnetic field 1074 is induced across the channel between the control gate 1052 and the modulated gate 1054.

The magnetic field 1074 is enhanced and can be stronger than the magnetic field 924 because of contributions to the magnetic field 1074 by the width of the metal line 1068. The magnetic field 1074 is further enhanced and made stronger by the use of soft magnetic material 1078 (e.g., Fe, Ni, Mo, Co, Zn, or others) included in the interlayer dielectric material between the control gate 1052 and the modulated gate 1054. A carrier path between the control gate 1052 and the modulated gate 1054 can be made longer by the magnetic field 1074.

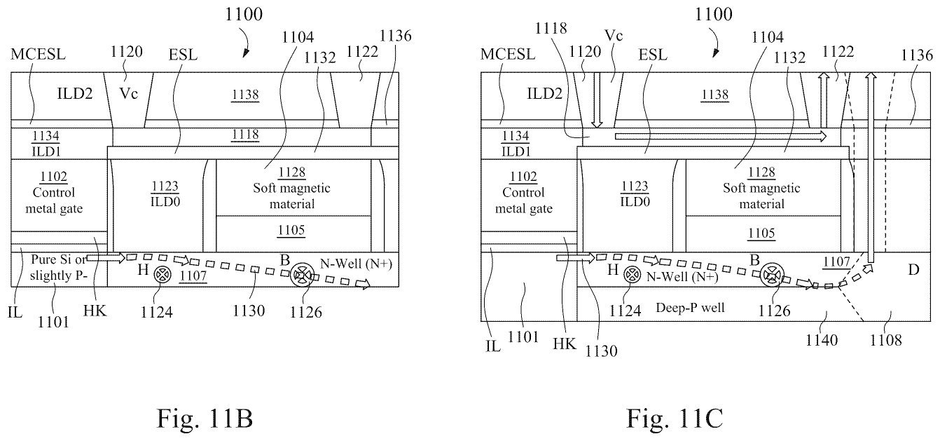

FIG. 11A is a top view of an example high voltage device 1100 that includes multiple gate structures in series between a source region and a drain region, according to some embodiments, and FIG. 11B is a cross-sectional view of the example high voltage device 1100 on a substrate 1101 (e.g., pure Si or slightly P-type) along a cut line 1103. The example high voltage device 1100 includes a control gate 1102, an auxiliary gate 1104 comprising soft magnetic material 1128 (e.g., Fe, Ni, Mo, Co, Zn, or others) and dielectric material 1105 disposed above an N-well 1107 in the substrate 1101, a source region 1106, and a drain region 1108. The control gate 1102 and the auxiliary gate 1104 are disposed between the source region 1106 and the drain region 1108, with the control gate 1102 disposed closer to the source region 1106 and the auxiliary gate 1104 disposed closer to the drain region 1108. The high voltage device 1100 also includes a source terminal 1110 for the source region 1106, a drain terminal 1112 for the drain region 1108, and a control gate terminal 1114 for the control gate 1102.

A metal line 1118 is coupled to a first VIA 1120 above the interlayer dielectric material layer 1123 between the control gate 1102 and the auxiliary gate 1104, and is coupled to a second VIA 1122 above the auxiliary gate 1104. The metal line 1118 is disposed above a channel region between the control gate 1102 and the auxiliary gate 1104 (e.g., below the interlayer dielectric material layer 1123) and a channel region below the auxiliary gate 1104. The metal line 1118 is separated from the interlayer dielectric material layer 1123 and the auxiliary gate 1104 by an etch stop layer (ESL 1132). The high voltage device 1100 further includes an ILD1 layer 1134, a metal contact etch stop layer (MCESL 1136), and an ILD2 layer 1138.

When currents are applied between the first VIA 1120 and the second VIA 1122, a magnetic field 1124 is induced across the channel region between the control gate 1102 and the auxiliary gate 1104 and a magnetic field 1126 is induced across the channel region below the auxiliary gate 1104. The magnetic field 1126 is stronger than the magnetic field 1124 because of the use of soft magnetic material 1128 (e.g., Fe, Ni, Mo, Co, Zn, or others). A carrier path 1130 between the control gate 1102 and an end of the auxiliary gate 1104 is made longer by the magnetic field 1124 and the magnetic field 1126.

FIG. 11C is a cross-sectional view of an example high voltage device 1100 along the cut line 1103, in accordance with some embodiments. In this example, the high voltage device 1100 includes the components described with respect to FIGS. 11A and 11B, but also includes a deep P-well 1140 formed in the substrate 1101 underneath the N-well 1107. The deep P-well 1140 provides a bottom boundary for carrier path 1130 and forces the carrier path 1130 to curve upward into the drain region 1108. Ordinary Magnetoresistance (ORM) makes the carrier path 1130 increase in length thereby causing larger breakdown voltage (BV) for the high voltage device 900. The Reverse P-N junction between the N-well 1107 and the deep P-well 1140 makes the carrier path 1130 return to the N+ channel.

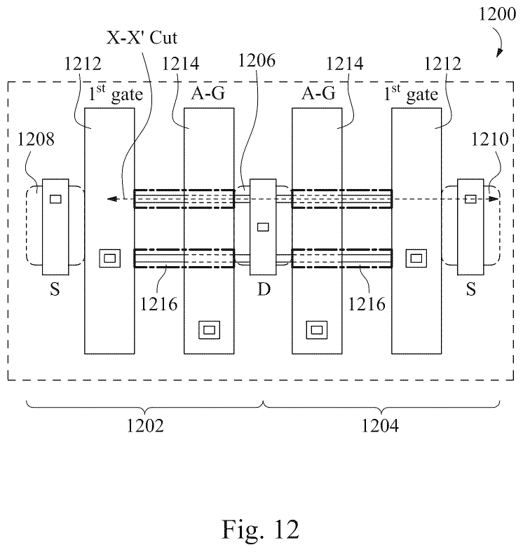

FIG. 12 is a top view of an example semiconductor structure 1200 that includes multiple gate structures in series between a source region and a drain region, according to some embodiments. The example semiconductor structure 1200 illustrates a configuration with symmetry by drain wherein a first high voltage device 1202 and a second high voltage device 1204 share a drain region 1206, and the first high voltage device 1202 has a first source region 1208 and the second high voltage device 1204 has a second source region 1210. In this example, each of the first high voltage device 1202 and the second high voltage device 1204 includes a control gate 1212 and an auxiliary gate 1214. Metal lines 1216 are disposed above a channel region between the control gates 1212 and the auxiliary gates 1214. When a current is applied in the metal lines 1216, magnetic fields are induced across channels between the control gates 1212 and the auxiliary gates 1214, which can increase the current paths in the channel regions and increase the breakdown voltage of the first high voltage device 1202 and the second high voltage device 1204. By sharing the drain region 1206, two high voltage devices can be formed using less surface area than two high voltage devices that do not share a drain region.

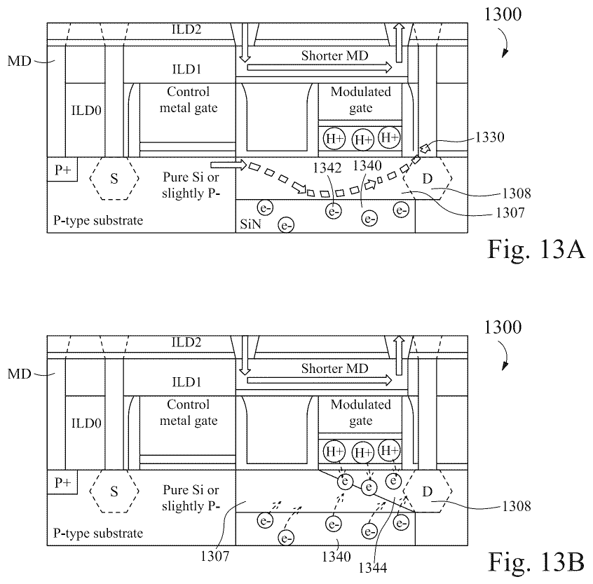

FIG. 13A is a cross-sectional view of the high voltage device 1300 that includes multiple gate structures in series between a source region and a drain region, according to some embodiments. FIG. 13A illustrates on-state operation of the high voltage device 1300, and FIG. 13B is a cross-sectional view of the high voltage device 1300 that illustrates off-state operation of the high voltage device 1300. In the example of FIG. 13A, a deep P-well 1340 formed from doped SiN has carriers 1342 that forces the carrier path 1330 to curve upward into the drain region 1308. In various embodiments, the SiN is filling with negative charging (e.g., electrons from on-state current being trapped by the Si₃N₄). The negative electric field between the N-well 1307 and the trapping layer 1340 makes the carrier path 1330 return to the N+ channel. In the example of FIG. 13B, in the off-state, the trapping layer 1340 can reduce the size of a depletion region 1344 by the charge injected into the depletion region from the trapping layer 1340.

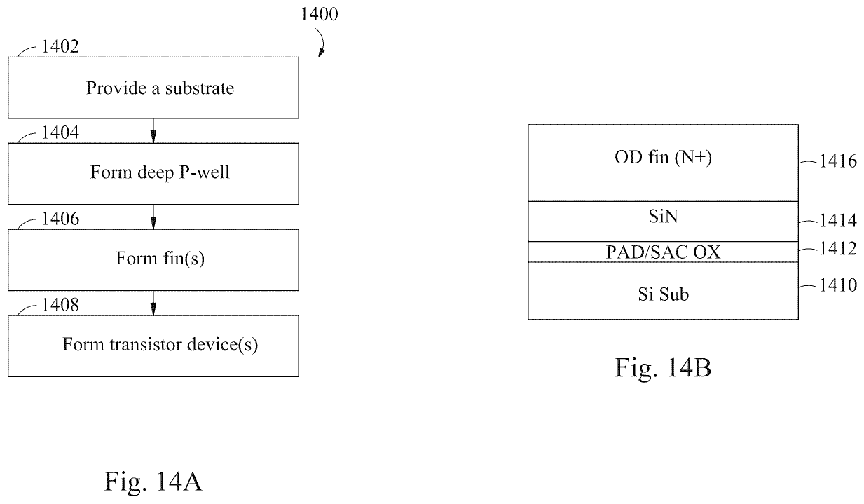

FIG. 14A is a flow diagram of an example method 1400 for fabricating a semiconductor device, according to some embodiments. For illustrative purposes, the operations illustrated in FIG. 14A will be described with reference to FIG. 14B, which provides a cross-sectional view of a semiconductor device at a stage of fabrication, according to some embodiments. It should be noted that method 1400 may not produce a complete semiconductor device. The method 1400 is merely an example, and is not intended to limit the present disclosure beyond what is explicitly recited in the claims. Additional steps may be provided before, during, and after example method 1400, and some of the steps described can be moved, replaced, or eliminated for additional embodiments of example method 1400. Further, it is understood that parts of the semiconductor device may be fabricated by typical semiconductor technology process flow, and thus some processes are only briefly described herein.

At block 1402, the example method 1400 includes providing a substrate. Referring to the example of FIG. 14B, a substrate 1410 is provided.

At block 1404, the example method 1400 includes forming a deep P-well in a substrate, which includes forming a PAD and/or Self-Aligned Contact (SAC) oxide layer over the substrate, and forming a SiN layer over parts of the substrate. Referring the example of FIG. 14B, a PAD/SAC oxide layer 1412 is formed over the substrate 1410, and a SiN layer 1414 is formed over the PAD/SAC oxide layer 1412.

At block 1406, the example method 1400 includes forming one or more fins. Referring the example of FIG. 14B, a fin 1416 is formed over the SiN layer 1414.

At block 1408, the example method 1400 includes forming a transistor device in the fin that includes multiple gate structures in series between a source region and a drain region, according to some embodiments. The transistor device includes a control gate and a secondary gate. In some embodiments, the secondary gate is a modulated gate. In some embodiments, the secondary gate is a depleted gate. In some embodiments, the secondary gate is an anti-type depleted gate. In some embodiments, the secondary gate is an auxiliary gate made of soft magnetic material. In various embodiments, forming a transistor device may be performed by any of method 330, method 550, method 650, or others.

The example high voltage devices have several designable features including: (a) heavy doping and gate modulator of the fin channel; (b) adjustable feature of the modulated gate; (c) tunable charge injection of the depleted gate; (d) the number of modulated gates; (e) the width of the modulated gate; and (f) magnetoresistance feature by layout design.

In some aspects, the techniques described herein relate to a semiconductor device, including: a first transistor including: a first source region and a drain region in a substrate; a first gate structure disposed above a first channel region in the substrate and between the first source region and the drain region, the first gate structure including a first gate dielectric disposed above the first channel region and a first gate electrode disposed above the first gate dielectric; and a second gate structure disposed above a second channel region in the substrate and between the first gate structure and the drain region, wherein the first gate structure is disposed closer to the first source region and the second gate structure is disposed closer to the drain region.

In some aspects, the techniques described herein relate to a semiconductor device, wherein the second gate structure includes a tunneling oxide layer above the second channel region, a trapping layer above the tunneling oxide layer, a control oxide layer above the tunneling oxide layer, and a work function metal layer above the control oxide layer.

In some aspects, the techniques described herein relate to a semiconductor device, wherein: the work function metal layer includes one or more of Ag, Au, Al, Rh, W, Mo, Zn, Co, Ru, Nb, Ti, Ta, Zr, TiN, Brass, Phosphor bronze, or Cast steel; the control oxide layer includes one or more of Si, Hf, La, Zr, Zn, or Y; the trapping layer includes one or more of Si, Ge, InSb, InAs, InP, N, Hf, Zr, Zn, or Y; and the tunneling oxide layer includes one or more of Si or O.

In some aspects, the techniques described herein relate to a semiconductor device, wherein: the control oxide layer has a thickness that is thicker than a thickness of the tunneling oxide layer; and the second channel region has a doping concentration that is thicker than a doping concentration of the first channel region.

In some aspects, the techniques described herein relate to a semiconductor device, wherein the first transistor has a first polarity type (e.g., NMOS), and the work function metal layer includes a low work function metal.

In some aspects, the techniques described herein relate to a semiconductor device, wherein the first transistor has a second polarity type (e.g., PMOS), and the work function metal layer includes a high work function metal.

In some aspects, the techniques described herein relate to a semiconductor device, wherein the second gate structure includes a tunneling oxide layer above the second channel region and a trapping layer including a poly silicon layer doped with negative ions above the tunneling oxide layer.

In some aspects, the techniques described herein relate to a semiconductor device, further including a spacer that bounds a sidewall of the second gate structure, wherein the spacer is doped with negative ions.

In some aspects, the techniques described herein relate to a semiconductor device, wherein the second channel region includes an N-well and the second gate structure includes a P-N reverse junction above the second channel region and a trapping layer including a poly silicon layer doped with positive ions above the P-N reverse junction.

In some aspects, the techniques described herein relate to a semiconductor device, further including: a second source region in the substrate, wherein the drain region is between the first source region and the second source region; and a second transistor including: the second source region and the drain region; a first gate structure disposed above a first channel region in the substrate and between the second source region and the drain region, the first gate structure including a first gate dielectric disposed above the first channel region and a first gate electrode disposed above the first gate dielectric; and a second gate structure disposed above a second channel region in the substrate and between the second source region and the drain region, wherein the first gate structure is disposed closer to the second source region and the second gate structure is disposed closer to the drain region; wherein the first transistor and the second transistor are electrically coupled to the drain region.

In some aspects, the techniques described herein relate to a method, including: forming a deep P-well in a substrate; forming a fin over the deep P-well and the substrate; and forming a transistor device in the fin, the transistor device including: a source region and a drain region, a first gate structure disposed above a first channel region in the substrate and including a first gate dielectric disposed above the first channel region and a first gate electrode disposed above the first gate dielectric, a second gate structure disposed above a second channel region in the substrate and between the first gate structure and the drain region; an interlayer dielectric layer region between the first gate structure and the second gate structure; and a metal layer over the interlayer dielectric layer region; wherein the second channel region includes an N-well and wherein the second channel region is disposed above the deep P-well.

In some aspects, the techniques described herein relate to a method, wherein forming the deep P-well includes: forming an oxide layer over the substrate; and forming a SiN layer over the oxide layer.

In some aspects, the techniques described herein relate to a method, further including forming a soft magnetic material in the interlayer dielectric layer region.

In some aspects, the techniques described herein relate to a method, further including: extending the metal layer over the second gate structure; and forming soft magnetic material in the second gate structure.

In some aspects, the techniques described herein relate to a method, further including: extending the metal layer over the second gate structure; and forming the second gate structure with a first oxide layer, a trapping layer including small band gap material over the first oxide layer, a second oxide layer over the trapping layer, a work function metal layer over the second oxide layer.

In some aspects, the techniques described herein relate to a semiconductor device, including: a source region and a drain region in a substrate; a first gate structure disposed above the substrate and between the source region and the drain region closer to the source region; and a second gate structure disposed above the substrate and between the source region and the drain region closer to the drain region, the second gate structure having a first oxide layer, a trapping layer including small band gap material over the first oxide layer, and a second oxide layer over the trapping layer.

In some aspects, the techniques described herein relate to a semiconductor device, wherein the second gate structure has a width that is approximately equal to a width of the first gate structure.

In some aspects, the techniques described herein relate to a semiconductor device, wherein the second gate structure has a width that is at least 1.5 times to 15 times a width of the first gate structure.

In some aspects, the techniques described herein relate to a semiconductor device, further including: a third gate structure having a first oxide layer, a trapping layer including small band gap material over the first oxide layer, and a second oxide layer over the trapping layer, the third gate structure disposed between the second gate structure and the drain region, and the third gate structure having a width that is approximately equal to the width of the first gate structure a width of the second gate structure.

In some aspects, the techniques described herein relate to a semiconductor device, further including: a third gate structure having a doped polysilicon layer, the third gate structure disposed between the second gate structure and the drain region, and the third gate structure having a width that is approximately equal to the width of the first gate structure and a width of the second gate structure.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A semiconductor device, comprising:
a first transistor comprising:
a first source region and a drain region in a substrate;
a first gate structure disposed on a first channel region in the substrate and between the first source region and the drain region, the first gate structure comprising a first gate dielectric disposed on the first channel region and a first gate electrode disposed on the first gate dielectric; and
a second gate structure disposed on a second channel region in the substrate and between the first gate structure and the drain region, wherein the first gate structure is disposed closer to the first source region and the second gate structure is disposed closer to the drain region.

2. The semiconductor device of claim 1, wherein the second gate structure comprises a tunneling oxide layer on the second channel region, a trapping layer on the tunneling oxide layer, a control oxide layer on the tunneling oxide layer, and a work function metal layer on the control oxide layer.

3. The semiconductor device of claim 2, wherein:
the work function metal layer comprises one or more of Ag, Au, Al, Rh, W, Mo, Zn, Co, Ru, Nb, Ti, Ta, Zr, TiN, Brass, Phosphor bronze, or Cast steel;
the control oxide layer comprises one or more of Si, Hf, La, Zr, Zn, or Y;
the trapping layer comprises one or more of Si, Ge, InSb, InAs, InP, N, Hf, Zr, Zn, or Y; and
the tunneling oxide layer comprises one or more of Si or O.

4. The semiconductor device of claim 2, wherein:
the control oxide layer has a thickness that is thicker than a thickness of the tunneling oxide layer; and
the second channel region has a doping concentration that is thicker than a doping concentration of the first channel region.

5. The semiconductor device of claim 2, wherein the first transistor has a first polarity type, and the work function metal layer comprises a low work function metal.

6. The semiconductor device of claim 2, wherein the first transistor has a second polarity type, and the work function metal layer comprises a high work function metal.

7. The semiconductor device of claim 1, wherein the second gate structure comprises a tunneling oxide layer on the second channel region and a trapping layer comprising a poly silicon layer doped with negative ions on the tunneling oxide layer.

8. The semiconductor device of claim 7, further comprising a spacer that bounds a sidewall of the second gate structure, wherein the spacer is doped with negative ions.

9. The semiconductor device of claim 1, wherein the second channel region comprises an N-well and the second gate structure comprises a P-N reverse junction on the second channel region and a trapping layer comprising a poly silicon layer doped with positive ions on the P-N reverse junction.

10. The semiconductor device of claim 1, further comprising:
a second source region in the substrate, wherein the drain region is between the first source region and the second source region; and
a second transistor comprising:
the second source region and the drain region;
a first gate structure disposed on a first channel region in the substrate and between the second source region and the drain region, the first gate structure comprising a first gate dielectric disposed on the first channel region and a first gate electrode disposed on the first gate dielectric; and
a second gate structure disposed on a second channel region in the substrate and between the second source region and the drain region, wherein the first gate structure is disposed closer to the second source region and the second gate structure is disposed closer to the drain region;
wherein the first transistor and the second transistor are electrically coupled to the drain region.

11. A method, comprising:
forming a deep P-well in a substrate;
forming a fin over the deep P-well and the substrate; and
forming a transistor device in the fin, the transistor device comprising:
a source region and a drain region,
a first gate structure disposed on a first channel region in the substrate and comprising a first gate dielectric disposed on the first channel region and a first gate electrode disposed on the first gate dielectric,
a second gate structure disposed on a second channel region in the substrate and between the first gate structure and the drain region;
an interlayer dielectric layer region between the first gate structure and the second gate structure; and
a metal layer over the interlayer dielectric layer region;
wherein the second channel region comprises an N-well and wherein the second channel region is disposed on the deep P-well.

12. The method of claim 11, wherein forming the deep P-well comprises:
forming an oxide layer over the substrate; and
forming a SiN layer over the oxide layer.

13. The method of claim 11, further comprising forming a soft magnetic material in the interlayer dielectric layer region.

14. The method of claim 11, further comprising:
extending the metal layer over the second gate structure; and
forming soft magnetic material in the second gate structure.

15. The method of claim 11, further comprising:
extending the metal layer over the second gate structure; and
forming the second gate structure with a first oxide layer, a trapping layer comprising small band gap material over the first oxide layer, a second oxide layer over the trapping layer, a work function metal layer over the second oxide layer.

16. A semiconductor device, comprising:
a source region and a drain region in a substrate;
a first gate structure disposed on the substrate and between the source region and the drain region closer to the source region; and
a second gate structure disposed on the substrate and between the source region and the drain region closer to the drain region, the second gate structure having a first oxide layer, a trapping layer comprising small band gap material over the first oxide layer, and a second oxide layer over the trapping layer.

17. The semiconductor device of claim 16, wherein the second gate structure has a width that is approximately equal to a width of the first gate structure.

18. The semiconductor device of claim 16, wherein the second gate structure has a width that is at least 1.5 times to 15 times a width of the first gate structure.

19. The semiconductor device of claim 16, further comprising:
a third gate structure having a first oxide layer, a trapping layer comprising small band gap material over the first oxide layer, and a second oxide layer over the trapping layer,
the third gate structure disposed between the second gate structure and the drain region, and
the third gate structure having a width that is approximately equal to the width of the first gate structure a width of the second gate structure.

20. The semiconductor device of claim 16, further comprising:
a third gate structure having a doped polysilicon layer,
the third gate structure disposed between the second gate structure and the drain region, and
the third gate structure having a width that is approximately equal to the width of the first gate structure and a width of the second gate structure.
